(19) United States
(12) Patent Application Publication
(10) Pub. No.: US 2008/0074927 A1
(43) Pub. Date: Mar. 27, 2008

(54) Memory array having an interconnect and method of manufacture

(76) Inventors: Franz Hofmann, Munich (DE); Michael Specht, Munich (DE); Nicolas Nagel, Dresden (DE); Josef Willer, Riemerling (DE)

Correspondence Address: SLATER & MATSIL LLP, 17950 PRESTON ROAD, SUITE 1000, DALLAS, TX, 75252, US

(21) Appl. No.: 11/525,547

(22) Filed: Sep. 22, 2006

(51) Int. Cl. G11C 16/04

(52) U.S. Cl. 365/185.17

(57) ABSTRACT

A memory array includes first, second, third and forth memory cell strings. Each of the first, second, third, and fourth memory cell strings includes a number of serially-coupled memory cells, including a first memory cell and a last memory cell. A first interconnect is coupled to a first bit line and to each of the first, second, third and fourth memory cell strings. The first interconnect includes first, second, third and fourth string input select gates. Each input select gate has a first terminal coupled to the first bit line, and a second terminal coupled to one of the respective first, second, third or fourth memory cell strings.

### TECHNICAL FIELD

The present invention relates to memory devices, and more particularly to a memory array architecture having an interconnect structure and method of manufacture therefore.

### BACKGROUND

Memory arrays are widely used in many electronic devices, be they in dedicated, peripheral, or embedded form, and their implementation continues to expand into new applications. Non-volatile memory technologies, such as Flash, magnetoresistive random access memory (MRAM), and phase change memory (PCM) show particular promise, as the retention of data in these types of memories without the need for power provides significant advantages, especially in mobile applications.

An impediment slowing the wider adoption of memory devices, however, is the storage density a memory device can obtain. In particular, the number of memory cells, or more specifically bits, a memory device can contain is limited. The limitation is due to size of the memory cells, as well as how the memory cells are interconnected. In many instances, the interconnect structure requires a large footprint, which when taken over the array's entire area, can represent a significant portion of the array.

What is needed is an improved bit line interconnect structure that is more space efficient.

### SUMMARY OF THE INVENTION

In an embodiment of the invention, a memory array is provided including a plurality of memory cell strings comprising first, second, third and forth memory cell strings, each of the first, second, third, and fourth memory cell strings comprise a plurality of serially-coupled memory cells, including a first memory cell and a last memory cell, a first bit line, and a first interconnect, coupled to the first bit line and to each of the first, second, third and fourth memory cell strings, the first interconnect comprise respective first, second, third and fourth string input select gates, each input select gate having a first terminal coupled to the first bit line, and a second terminal coupled to one of the respective first, second, third or fourth memory cell strings.

Features of embodiments of the invention will be better understood when viewed in light of the following drawings and detailed description.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a portion of a memory array incorporating an interconnect in accordance with one embodiment of the present invention;

FIG. 2 illustrates a schematic representation of a common source memory array incorporating an interconnect in accordance with one embodiment of the present invention;

FIG. 3 illustrates a schematic representation of a virtual ground memory array incorporating an interconnect in accordance with one embodiment of the present invention;

FIG. 4 illustrates a method for manufacturing a memory array incorporating an interconnect in accordance with the present invention;

FIG. 5 illustrates exemplary processes specific to manufacturing the memory array of the present invention in a common source/drain line configuration;

FIG. 6 illustrates exemplary processes specific to manufacturing a memory array of the present invention in a virtual ground configuration;

FIG. 7 illustrates a cross-sectional view of a transistor employing an interconnect in accordance with one embodiment of the present invention;

FIG. 8A illustrates a top level view of a common source/drain line memory array portion in accordance with FIG. 2;

FIGS. 8B-8H illustrate a first cross-sectional view of a common source/drain line memory array portion in various states of manufacture in accordance with the present invention;

FIGS. 8I-8K illustrate a second cross-sectional view of a common source/drain line memory array portion in various states of manufacture in accordance with the present invention;

FIG. 9A illustrates a top level view of a virtual ground memory array portion in accordance with FIG. 3;

FIGS. 9B-9S illustrate a first cross-sectional view of a virtual ground memory array portion in various states of manufacture in accordance with the present invention; and

FIGS. 9T-9V illustrate a second cross-sectional view of a virtual ground memory array portion in various states of manufacture in accordance with the present invention.

For clarity, previously described features retain their reference numerals in subsequent drawings.

### DETAILED DESCRIPTION OF ILLUSTRATIVE EMBODIMENTS

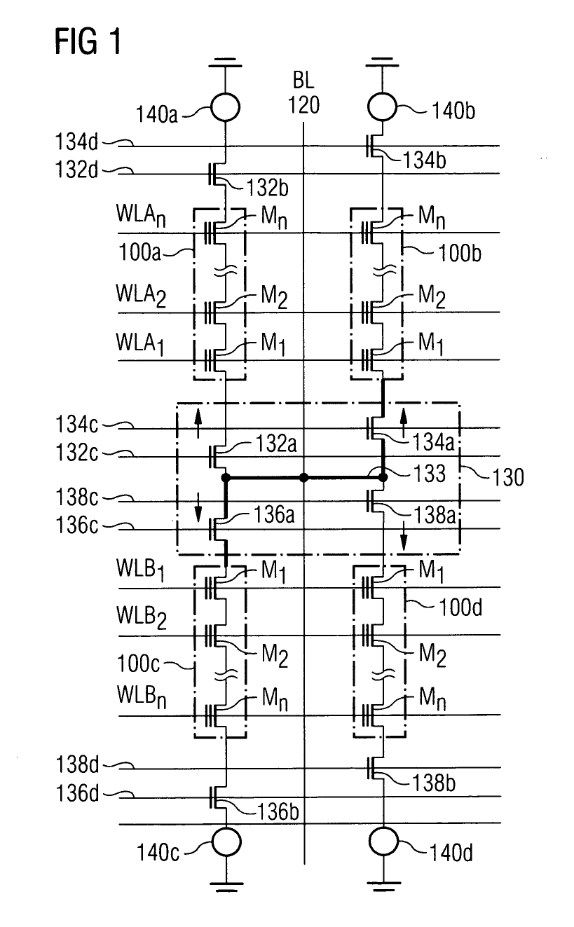

FIG. 1 illustrates a portion of a memory array 100 incorporating a bit line interconnect in accordance with one embodiment of the present invention. The array portion 100 includes a plurality of memory cell strings including first, second, third and fourth memory cell strings 100a, 100b, 100c, and 100d, each memory string including a plurality of serially-coupled (source-to-drain) memory cells, as shown in the NAND configuration. Each of the memory cell strings includes a first memory cell (M₁) and a last memory cell (Mₙ), and any number of memory cells may be used within a string, for example, 8, 16, and 32 cells, and each of the memory cells M₁-Mₙ may store single bit or multiple bits of data. In a particular embodiment, the memory cells M₁-Mₙ are non-volatile memory cells, examples being Flash, magnetoresistive random access memory (MRAM) cells, phase change memory cells (PCM), and other non-volatile memory structures known in the art. Furthermore, within one of these types of memory technologies, the structure of the memory cell may vary, for example, in Flash technology, the memory cell may be of a floating gate or charge trapping structure, planar channel or recessed channel, or may be a FinFET cell. Those skilled in the art will appreciate that the present invention is not limited to a memory cell of any particular construction, and various types of memories may be used in accordance herewith.

As shown, the first and second memory cell strings 100a and 100b are coupled to a first group of word lines WLA₁-WLAₙ, and third and fourth memory cell strings 100c and 100d are coupled to a second set of word lines WLB₁-WLBₙ. Further illustrated, the first and third memory cell strings 100a and 100c are substantially aligned along a first longitudinal axis, and the second and fourth memory cell strings 100b and 100d are substantially aligned along a second longitudinal axis. In an alternative embodiment of the invention, the first and third memory strings 100a and 100c may be aligned along a first zig-zag structure and the second and fourth memory cell strings 100b and 100d may be aligned along a second zig-zag structure, wherein the first zig-zag structure and the second zig-zag structure do not cross each other, and in one embodiment of the invention, run substantially parallel to each other. It should be mentioned that the invention is not limited to the above-mentioned structures. Any other structure may be used within the scope of the invention.

Further included in the array portion 100 is a bit line 120 operable to provide a bit line voltage and/or bit line current to each of the first, second, third and fourth memory cell strings 100a, 100b, 100c, and 100d. As shown, the bit line 120 is disposed between the aforementioned first and second longitudinal axes, a configuration which permits bit line contact to be made to each of the memory cell strings 100a, 100b, 100c, and 100d.

In one embodiment of the invention, the bit line may be formed from various low resistance materials, such as tungsten, aluminum, and the like. Furthermore, the bit line 120 may be 50 nm wide (horizontal dimension, as shown), or smaller as permitted by processing capabilities.

The array portion 100 further includes an interconnect (in the following also referred to as a bit line interconnect) 130 operable to distribute the bit line voltage and/or bit line current to each of the memory cell strings 100a, 100b, 100c, and 100d. The bit line interconnect 130 includes first, second, third and fourth string select gates 132a, 134a, 136a, and 138a as shown, which operate to provide the bit line voltage to each of the memory cell strings 100a, 100b, 100c, and 100d. To facilitate the explanation of the invention, the select gates are described as “input” select gates, as they are operable to pass current (as indicated by the illustrated arrows) to their respective memory cell string 100a-100d. In other embodiments of the invention, which are shown below, the bit line interconnect will include “output” select gates which receive current passed through the gates corresponding memory cell string. The bit line interconnect 130 is merely located between and coupled to the memory cell strings 100a, 100b, 100c, and 100d. No other peripheral units, except for the respective bit line and the components coupled to the bit line are coupled to the bit line interconnect 130. In other words, the bit line interconnect 130 provides a local distribution of the bit line voltage and/or bit line current provided via the bit line to one or a plurality of the coupled memory cell strings 100a, 100b, 100c, and 100d.

The input select gates include a first terminal coupled to the bit line, and a second terminal coupled to a respective one of the first, second, third or fourth memory cell strings. In the exemplary embodiment shown, each of the select gates couples to the first memory cell of the respective memory string, e.g., the first string input select gate 132a is coupled to the first memory cell (M₁) of the first memory cell string (100a), and so on for the second, third and fourth string input select gates. Furthermore, each of the input select gates 132a, 134a, 136a, and 138a are transistors in which the first terminal (source/drain) is coupled to the bit line, the second terminal (source/drain) is coupled to the one of the memory cell strings, and the control terminal (gate) is coupled to receive a control signal 132c, 134c, 136c, and 138c, the control signal operable to control the conduction state of one or more of the input select gates.

In a particular embodiment of the invention, two of the input select gates are configured as through connections, the remaining two operable as switches. In the exemplary embodiment shown, the second and third input select gates 134a and 136a are configured as through connections to form a connection path 133, and the first and fourth input select gates 132a and 138a are configured as switches, the states of which are controlled by signals 132c and 138c. The through connection state may be achieved through several means, for example, by means of a forward-biased transistor, or by a conductive connection, such as a conductive via, a nanowire, or another physical interconnecting structure. When implemented as a transistor, the through connection may be achieved by providing a control signal to sufficiently forward bias the transistor, or by constructing the transistor such that it operates as a pass through element (e.g., a normally-on transistor, also referred to as permanently-on transistor). Those skilled in the art will appreciate that the type of structure used to achieve the through connection may vary depending upon the processing capabilities.

The above through connection arrangement is exemplary and others may be used in the alternative. For example, first and fourth input select gates 132a and 138a may be configured as through connections, and the second and third input select gates 134a and 136a may be configured as switches. Furthermore, two input select gates along the active area axis may be configured as select gates, e.g., first and third input select gates 132a and 136a, or second and fourth select gates 134a and 138a. Still further, the input select gates at each end of the respective memory cell string may be configured as through connections, for example, the first and second input select gates 132a and 134a, or the third and fourth input select gates 136a and 138a. All that is required is that at least one of the input select gate and the output select gate corresponding to each memory cell string be operable as a switch to control operation of the corresponding memory string.

Array portion 100 further includes select gates 132b, 134b, 136b and 138b, each referred to as an “output” select gate, as each is operable to receive current passed through a respectively coupled memory cell string. As shown, each output select gate has a first terminal (source/drain) which is coupled to the last memory cell within a particular string, a second terminal (source/drain) coupled to another voltage 140a, 140b, 140c, and 140d, and a control terminal for controlling the conduction state of the output select gate. Particular embodiments as to the connection of the output select gates are presented below.

During operation, a bit line voltage and/or bit line current is supplied to bit line 120 which is supplied to the bit line interconnect 130. Assuming that the connection path 133 is provided, and further assuming that it is the first memory cell string 100a which is to be read from or written to, first string input select gate 132a would be turned on (controlled to a conductive state), and first string output select gate 132b would be turned on, thereby providing a current path for the first memory cell string 100a. The other memory cell strings 100b, 100c, and 100d are turned off by turning off output select gates 134b, 136b and 138b, as well as input select gate 138a. It can be seen that any of the memory strings 100a-100d can be individually activated by a similar process and with the connection path 133, or alternatively with the connection path 133 formed between the first and fourth input select gates 132a and 138a, as mentioned above.

Output select gate voltages 140a, 140b, 140c and 140d may be provided through several different arrangements, depending upon the desired memory device architecture. For example, a common source/drain line architecture may be employed, whereby the output select gate voltages 140a and 140b are provided via a first common source line, and output select gate voltages 140c and 140d are provided via a second common source line. Alternatively, additional bit line interconnects may be used to supply the output select gate voltages. Each of the embodiments is described in further detail below.

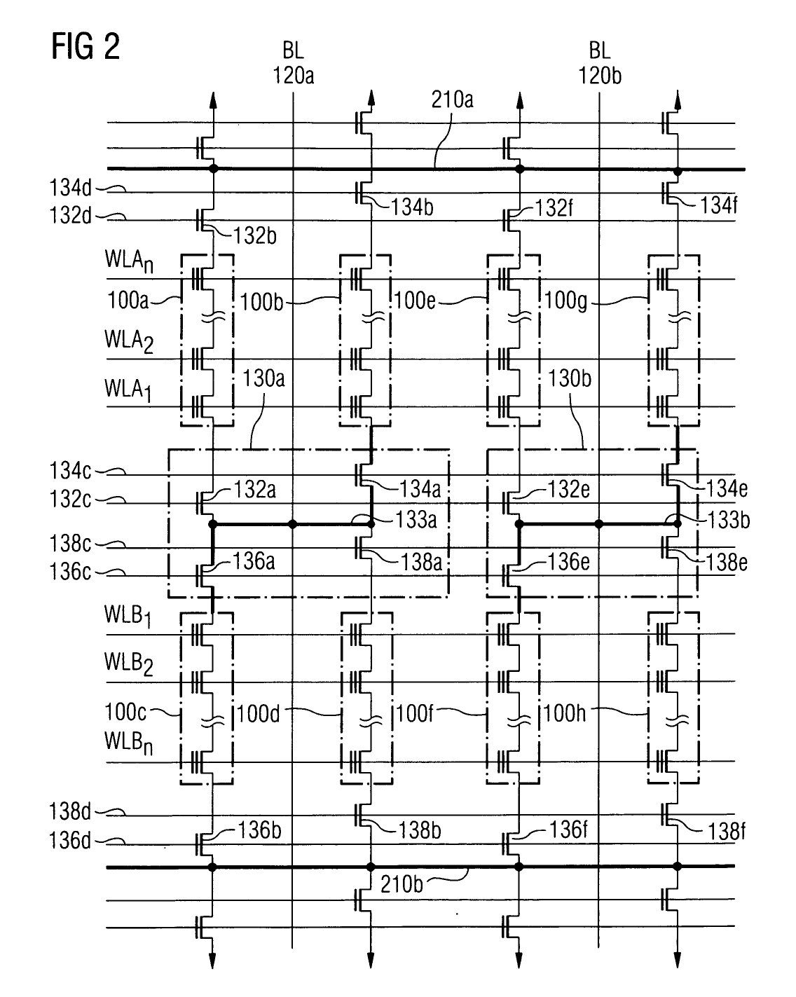

FIG. 2 illustrates a schematic representation of a common source line memory array incorporating a bit line interconnect in accordance with one embodiment of the present invention, with previously identified features retaining their reference numerals. As shown, first second string output select gates 132b and 134b are coupled to a first common source line 210a, and third and fourth string output select gates 136b and 138b are coupled to a second common source line 210b. Through the output select gates 132b and 134b, the last memory cell in each of the first and second cell strings 100a and 100b are coupled to the first common source line 210a, and similarly output select gates 136b and 138b provide coupling between the last memory cell in each of the third and fourth strings 100c and 100d to the second common source line 210b.

The common source line configuration further includes a second bit line interconnect 130b which is coupled to a second bit line 120b, and to fifth, sixth, seventh and eighth memory cell strings 100e, 100f, 100g, and 100h, via input select gates 132e, 134e, 136e and 138e, respectively. Output select gates 132f, 134f, 136f and 138f operate to complete the circuit between the second bit line 120b and either the first common source line 210a (for the fifth and seventh memory cell strings 100e and 100g), or the second common source line 210b (for the sixth and eighth memory cell strings 100f and 100h).

In a particular embodiment of the invention, the aforementioned through connection arrangement employed in the first bit line interconnect 130a, which has the same structure as the bit line interconnect 130 of the embodiment shown in FIG. 1, is repeated in the second bit line interconnect 130b. In particular, two of the four input select gates will comprise through connections for forming a connection path 133b, the remaining two of the four input select gates operable as switches in the manner as described in the first bitline interconnect 130a. Further specifically, either the fifth string input select gate 132e or the sixth string input select gate 134e will form a through connection, and correspondingly either the seventh or eighth string input select gate 136e or 138e will form a through connection. In an alternative embodiment, the first second interconnects 130a and 130b are differently configured; for example, the first interconnect employs the first and fourth input select gates as through connections, whereas the second interconnect 130b implements the sixth and seventh input select gates 134e and 136e as through connections. Still further, one of the interconnects may not employ a through connection at all.

The skilled person will appreciate that the array portion is repeatable. For example, an additional bit line and four memory cell strings are coupled together by a further bit line interconnect that may be included between the first and second common source lines 210a and 210b. Further, the illustrated array portion may be repeatedly arranged next to one another.

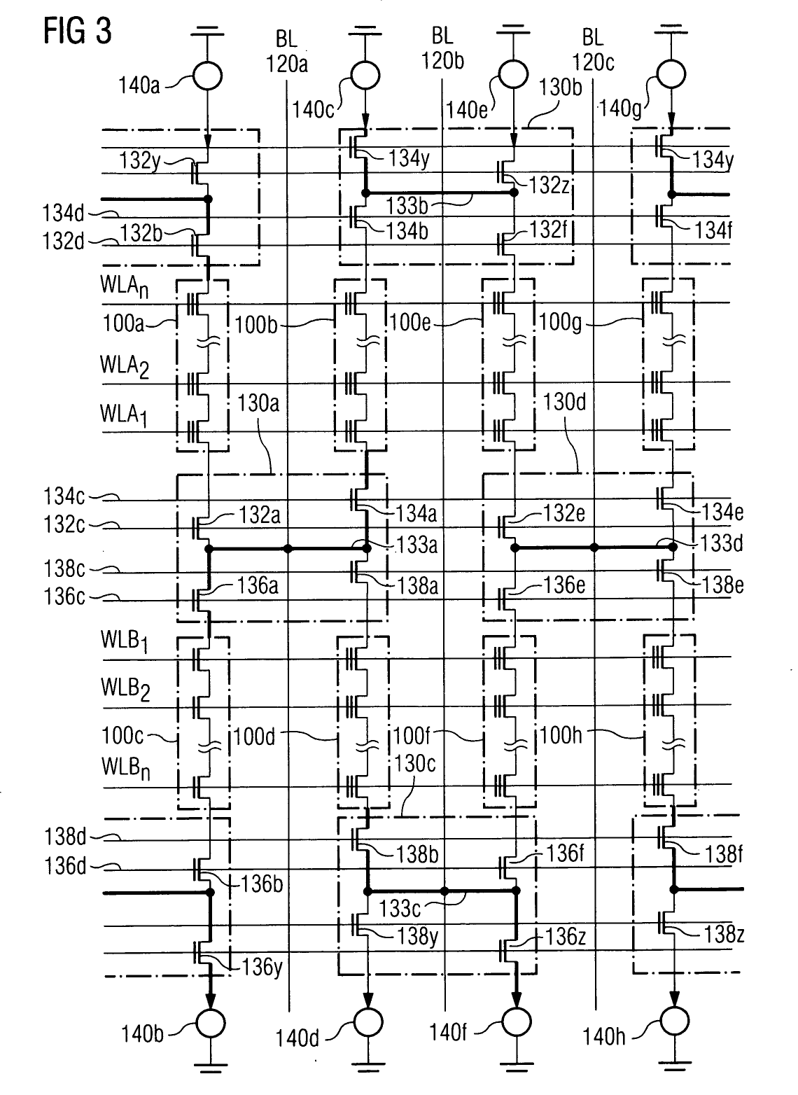

FIG. 3 illustrates a schematic representation of a virtual ground memory array incorporating a bit line interconnect in accordance with one embodiment of the present invention, with previously identified features retaining their reference numerals. In this embodiment, the output select gate voltages 140a-140d are provided via additional bit line interconnects to allow biasing of the desired memory cell string.

As depicted, the memory array portion includes, in addition to the embodiment of FIG. 1, first, second, third and fourth bit line interconnects 130a, 130b, 130c and 130d, and fifth, sixth, seventh and eighth memory strings 100e, 100f, 100g and 100h. The first bit line interconnect 130a includes the input select gates 132a, 134a, 136a, and 138a, as earlier described. The second bit line interconnect 130b includes a second string output select gate 134b, a fifth string output select gate 132f, and two additional output select gates 134y and 132z coupled to memory cell strings extending above the drawing.

The third bit line interconnect 130c includes output select gates, particularly the fourth string output select gate 138b, the sixth string output select gate 136f, and two additional output select gates 138y and 136z coupled to memory cell strings extending below the drawing. The fourth bit line interconnect 130d includes input select gates, specifically the fifth string input select gate 132e, the sixth string input select gate 134e, a seventh string input select gate 136e, and an eighth string input select gate 138e.

Referring to the operation of the second bit line interconnect 130b, the second string output select gate 134b included therein is biased by the second bit line 120b. In particular, when activation of the second memory cell string 100b is desired, the second string output select gate 134b is biased by control signal 134d, thereby providing the voltage and/or current present on the second bit line 120b to be supplied to the last memory cell within the second memory cell string 100b. Concurrently, a first bit line voltage is applied to the first bit line 120a, which is supplied to the first memory cell in the second memory cell string 100b via the input select gate 134a, which in the illustrated embodiment, is configured as a through connection. In this manner, voltages from two bit lines may be applied to a memory cell string.

To ensure proper operation, contiguous memory strings along both the first and second bit lines 120a and 120b are deactivated. In such a process, input select gates 132a and 138a are turned off, output select gates 136b are turned off, output select gate 132z in the second interconnect 130b is turned off, and input select gates 136f and 138y in the third interconnect 130c are turned off.

The second interconnect structure further includes a fifth string output select gate 132f coupled between the last memory cell in the fifth string 100e and the second bit line 120b. The fifth string output select gate 132f is configured as a through connection in the illustrated embodiment, although in an alternative embodiment it may be configured as a switch.

Operation of the fifth string 100e is achieved by supplying a first voltage to the third bit line 120c, the first voltage is supplied to the first memory cell in the fifth string 100e by the fourth bit line interconnect 130d via input select gate 132e. A second voltage is supplied to the last memory cell in the fifth string 100e by the second bit line interconnect 130b via the output select gate 132f. Contiguous cell strings coupled along the second and third bit lines 120b and 120c are turned off, particularly, the second string 100b is deactivated by switching off its output select gate 134b, sixth string 100f is deactivated by switching off its output select gate 136f, seventh memory cell string 100g is deactivated by switching off its output select gate 134f, eighth memory cell string 100h is deactivated by switching off its input select gate 138e. Further, output select gate 132z and 138y are switched off to prevent their corresponding memory cells from conducting. Memory cell strings having 134y and 136z as output select gates will have switchable select gates that are turned off to prevent these strings from conducting.

In a particular embodiment of the invention, each of the bit line interconnects 130a-130d includes a connection path 133a-133d formed via two through connections within the bit line interconnect 130a-130d. Any of the aforementioned through connection arrangements may be employed. The second and third input select gates may be used, as shown in the illustrated embodiment. Alternatively, the first and fourth input select gates may be used as the through connections. Further, the first and third input select gates, or the second and fourth input select gates may be used, e.g., when the first bit line interconnect 130a is so arranged and the second interconnect 130b includes the same through connection arrangement. Still further, the first and second input select gates or the third and fourth select gates may be configured as the through connections. All that is required is that the input select gate and the output select gate corresponding to the same memory string (e.g., 134a and 134b corresponding to the second memory cell string 100b) are not both configured as through connections, as this would prevent controlling the activation of the string.

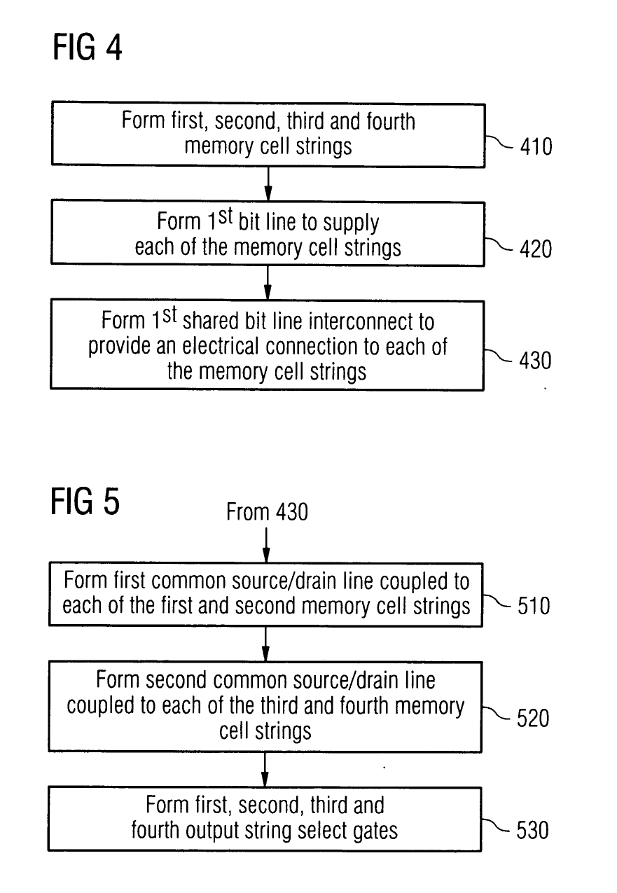

FIG. 4 illustrates a method for manufacturing a memory array incorporating a bit line interconnect in accordance with the present invention. The method includes a process 410 of forming first, second, third, and fourth memory cell strings, each of the memory cell strings including a plurality of serially-coupled memory cells, including a first memory cell and a last memory cell. The process of forming the serially-coupled memory cells will depend upon the type and structure of the cell. In a particular embodiment of the invention, those processes implemented in manufacturing Flash-type memory cells are employed, embodiments of which are further shown below. The memory cell strings may also be fabricated in MRAM, PCM, or other memory cell technologies.

Next at 420, a first bit line operable to provide a voltage to the memory cells in each of the first, second, third, and fourth memory cell strings is formed. In alternative embodiments, the formation of the bit line may be included in the construction of the first, second, third and fourth memory cell strings. In such a case, this operation is omitted.

At 430, a first bit line interconnect is formed, the interconnect operable to provide an electrical interconnection between the first bit line and each of the first, second, third and fourth strings. In a particular embodiment of this process, first, second, third and fourth string input select gates are constructed, each coupled between the first bit line and a respective one of the first, second, third or fourth memory cell strings. An exemplary process of 430 further includes the operation of configuring two of the first, second, third, and fourth string input select gates to operate as switches, and the remaining two of the first, second, third and fourth string input select gates to operate as through connections. Each of these processes is illustrated in greater detail below.

In a specific embodiment of the invention, the operation 410 of forming at least first, second, third, and fourth memory strings is carried out such that two of the memory cell strings (e.g., the first and third strings 100a and 100c) are substantially aligned along a first longitudinal axis, and that two other memory cell strings (e.g., the second and fourth strings 100b and 100d) are also substantially aligned along a second longitudinal axis. Further, operation 420 of forming a bit line is performed so as to form the bit line between the first and second longitudinal axes. This configuration enables the bit line to contact the bit line interconnects without interfering with or disturbing the control lines or active area disposed along the memory cell string. In one embodiment of the invention, the first longitudinal axis and the second longitudinal axis are substantially parallel to one another.

In a further specific embodiment, the operation of constructing the first, second, third and fourth input select gates comprises constructing field effect transistors for each of the input select gates. In this embodiment, each select gate FET will include a first terminal (e.g., a first source/drain terminal) coupled to the first bit line, a second terminal (e.g., a second source/drain terminal) coupled to one of the respective first, second, third or fourth memory cell strings, and a gate terminal operable to control conduction between the first and second terminals. Subsequently, the active regions between the first terminal and the second terminal of two of the first, second, third and fourth input select gate transistors are implanted to render those transistors conductive. An exemplary embodiment of this process is illustrated further below.

FIG. 5 illustrates exemplary processes specific to manufacturing the memory array of the present invention in a common source line configuration. These operations may be included in any of the aforementioned processes 410-430, or may be performed separately in other embodiments.

At 510, a first common source/drain line (e.g., 210a) is formed which is coupled to each of the last memory cells (Mₙ) in the first and second memory cell strings (e.g., 100a and 100b).

At 520, a second common source/drain line is formed which is coupled to each of the last memory cells (Mₙ) in the third and fourth memory cell strings, e.g., 100c and 100d.

At 530, the following structures are formed (i) a first string output select gate (e.g., 132b) coupled between the last memory cell in the first memory cell string and the first common source/drain line, (ii) a second string output select gate (e.g., 134b) coupled between the last memory cell in the second memory cell string and the first common source/drain line, (iii) a third string output select gate (e.g., 136b) coupled between the last memory cell in the third memory cell string and the second common source/drain line, and (iv) a fourth string output select gate (e.g., 138b) coupled between the last memory cell in the fourth memory cell string and the second common source/drain line. The resulting structure is as shown in FIG. 1.

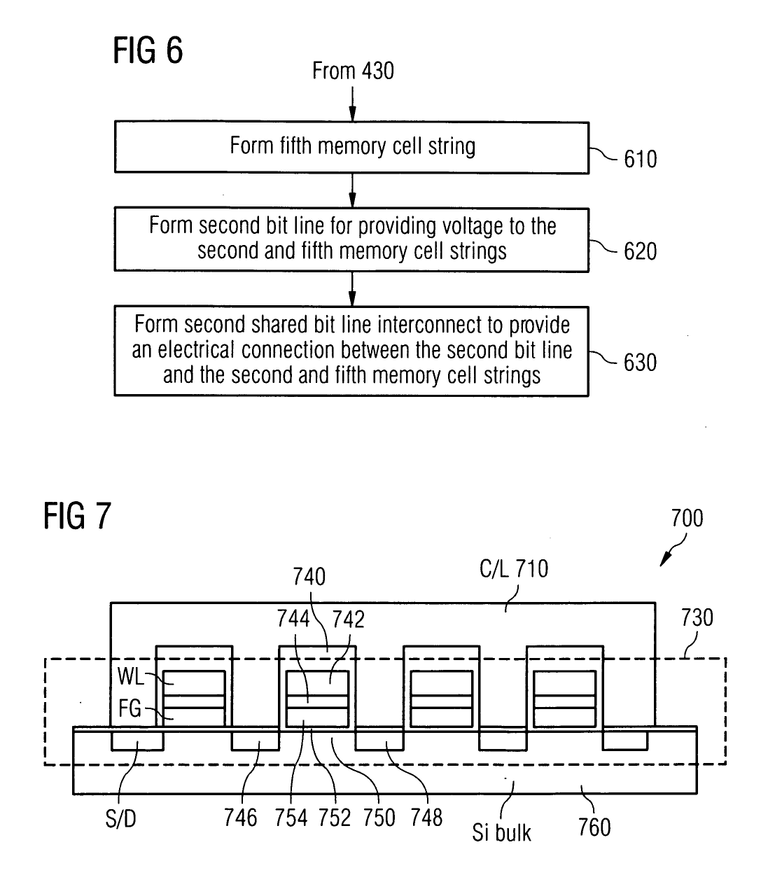

FIG. 6 illustrates exemplary processes specific to manufacturing the memory array of the present invention in a virtual ground configuration. These operations may be included in any of the aforementioned processes 410-430, or may be performed separately in other embodiments.

At 610, a fifth memory cell string (e.g., 100e) is formed, the fifth string including a plurality of serially-coupled memory cells including a first memory cell and a last memory cell. At 620, a second bit line (e.g., 120b) operable to provide a voltage to the memory cells in each of the second and fifth memory cell strings is formed.

At 630, a second bit line interconnect (e.g., 130b) is formed, the second bit line interconnect (e.g., 130b) operable to provide an electrical interconnection between the second bit line (e.g., 120b) and the second and fifth memory cell strings (e.g., 100b and 100e). In a particular embodiment of this process, a second string output select gate (e.g., 134b) and a fifth string output select gate (e.g., 132f) are constructed, the second string output select gate (e.g., 134b) being coupled between the second bit line (e.g., 120b) and the last memory cell in the second memory cell string (e.g., 100b), and the fifth string output select gate (e.g., 132f) being coupled between the second bit line (e.g., 120b) and the last memory cell in the fifth memory cell string (e.g., 100e). Process 630 may further include configuring one of the second and fifth string output select gates (e.g., 134b and 132f) to operate as a switch, and the remaining one of the second and fifth string output select gates (e.g., 134b and 132f) to operate as a through connection.

In a further specific embodiment, the operation of constructing the first, second, third and fourth input select gates (e.g., 130a, 130b, 130c and 130d) comprises constructing field effect transistors for each of the input select gates (e.g., 130a, 130b, 130c and 130d). In this embodiment, each select gate FET will include a first terminal (e.g., a first source/drain terminal) coupled to the first bit line (e.g., 120a), a second terminal (e.g., a second source/drain terminal) coupled to one of the respective first, second, third or fourth memory cell strings (e.g., 100a, 100b, 100c and 100d), and a gate terminal operable to control conduction between the first and second terminals. Subsequently, the gate terminal of two of the first, second, third and fourth input select gate transistors (e.g., 130a, 130b, 130c and 130d) are implanted to render those transistors conductive. An exemplary embodiment of this process is illustrated further below.

In a specific embodiment, the aforementioned operation of constructing the second and fifth output select gates (e.g., 134b and 132f) includes the process of constructing field effect transistors for each of the second and fifth output select gates (e.g., 134b and 132f), each having a first terminal (e.g., a first source/drain terminal) coupled to the first bit line, a second terminal (e.g., a second source/drain terminal) coupled to one of the respective second or fifth memory cell strings (e.g., 100b and 100e), and a gate terminal operable to control conduction between the first and second terminals.

In a specific embodiment of the invention, the operation 610 of forming a fifth memory cell string is carried out such that it extends along a third longitudinal axis, (the first and third strings extending substantially aligned along a first longitudinal axis, and the second and fourth strings extending substantially aligned along a second longitudinal axis). Further, operation 620 of forming a second bit line is performed so as to form the second bit line between the second and third longitudinal axes. In one embodiment of the invention, the first longitudinal axis, the second longitudinal axis and the third longitudinal axis are substantially parallel to one another.

FIG. 7 illustrates a cross-sectional view of a transistor arrangement 700 having a control line 710 disposed across the gate stack of each of the memory cells within the illustrated memory cell string 730. The transistor arrangement 700 may include a plurality of serially source-to-drain coupled memory cells 740 formed in, on or above a carrier 760. The carrier 760 may be a substrate, such as a semiconductor substrate. The semiconductor substrate may be formed from a silicon bulk substrate, although in an alternative embodiment of the invention, the semiconductor substrate may be a silicon-on-insulator (SOI) substrate. Any other suitable semiconductor material such as semiconductor compound material (e.g., a IV-IV semiconductor compound material (e.g., SiGe), a III-V semiconductor compound material (e.g., GaAs), and a II-VI semiconductor compound material) may be used in an alternative embodiment of the invention. Each of the memory cells 740 can be a charge storage memory cell such as a charge trapping memory cell or a floating gate memory cell. In the case of a floating gate memory cell 740, it includes a first source/drain region 746 and a second source/drain region 748. An active region 750 is provided between the first source/drain region 746 and the second source/drain region 748. Furthermore, a tunnel dielectric layer 752, e.g., made of an oxide such as silicon oxide, is disposed on or above the active region 750. In one embodiment of the invention, a floating gate region 754 is disposed on or above the tunnel dielectric layer 752, the floating gate region 754 being made of an electrically conductive material such as poly-silicon. In one embodiment of the invention, a control gate dielectric region 744 is disposed on or above the floating gate region 754, the control gate dielectric region 744 being made of a dielectric layer, e.g., made of an oxide such as silicon oxide or aluminum oxide. A control gate region is disposed on or above the control gate dielectric region 744, the control gate region is made of an electrically conductive material such as poly-silicon, and is connected to a word line 742. In operation, a channel may be established in the active region 750 enabling a current flow between the first source/drain region 746 and the second source/drain region 748 in response to the application of appropriate gate voltage, source voltage and drain voltage and a voltage applied to the control line 710. A voltage difference is applied between the control line 710 and one of the word lines, e.g., 742, the applied voltage difference producing a lower effective barrier thickness within the control gate dielectric region 744 of the cell 740. The reduction in the effective barrier of the control gate dielectric region 744 enables the use of lower programming and erase voltages.

An obstacle encountered in the employing the control line 710 to lower the programming and erase voltage is that the control line 710 can obstruct the NAND string's access to a bit line which is normally positioned were the control line 710 is implemented. The small footprint of the bit line interconnect allows it to be positioned between adjacent control lines to provide a switchable interconnection between a common bit line and two adjacent NAND memory strings.

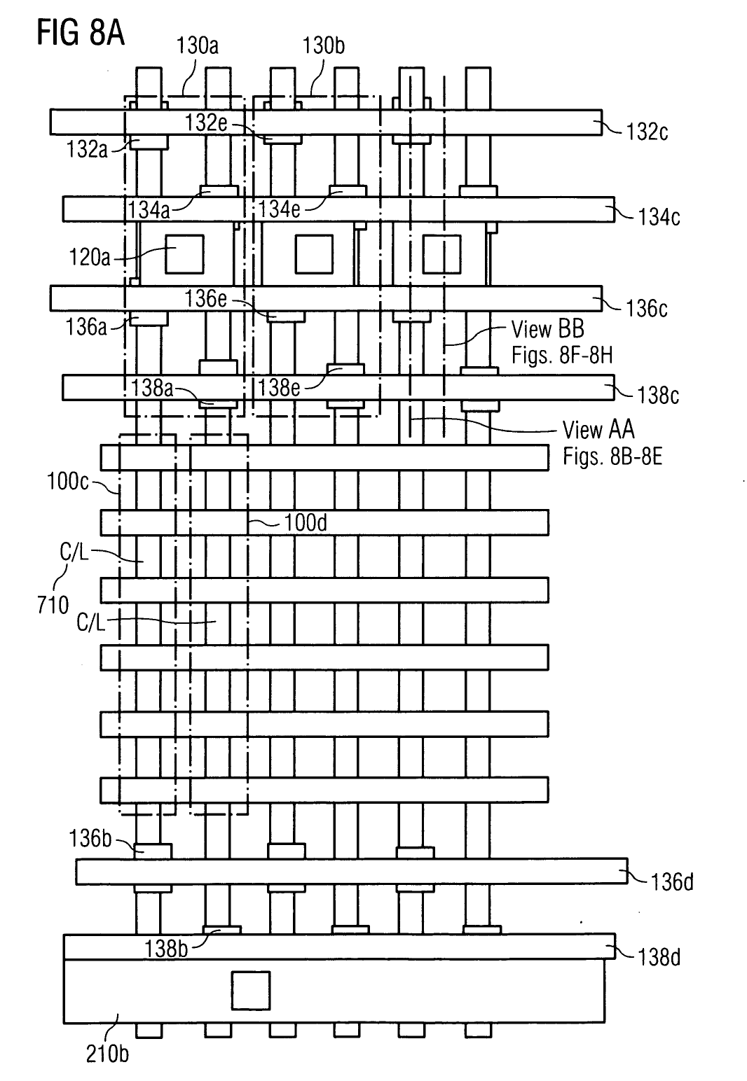

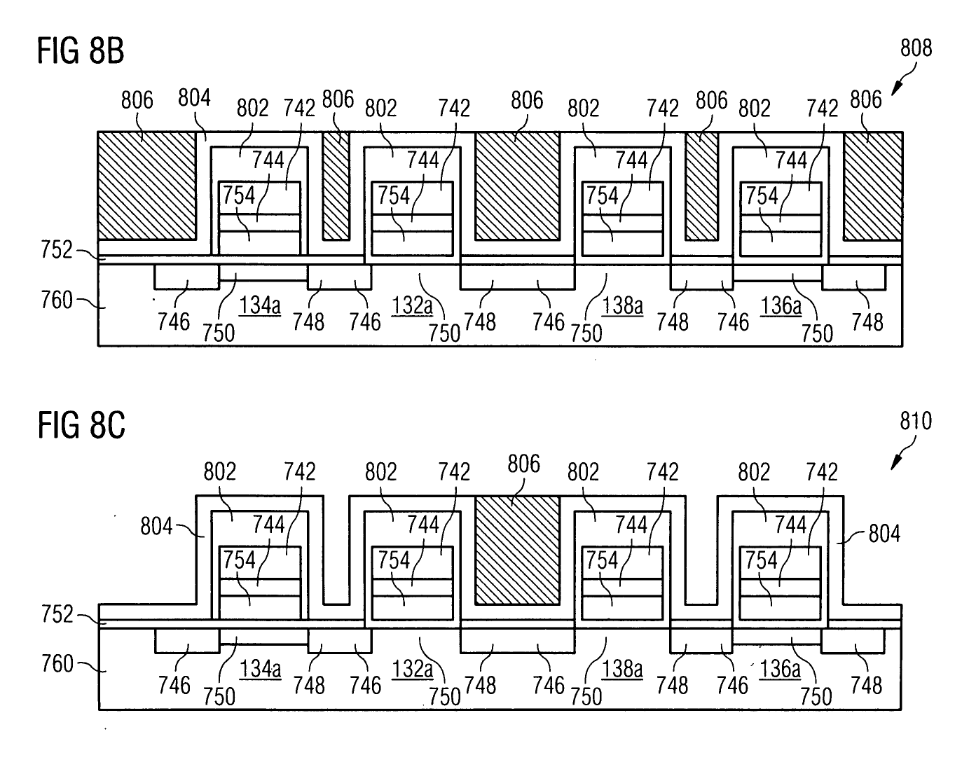

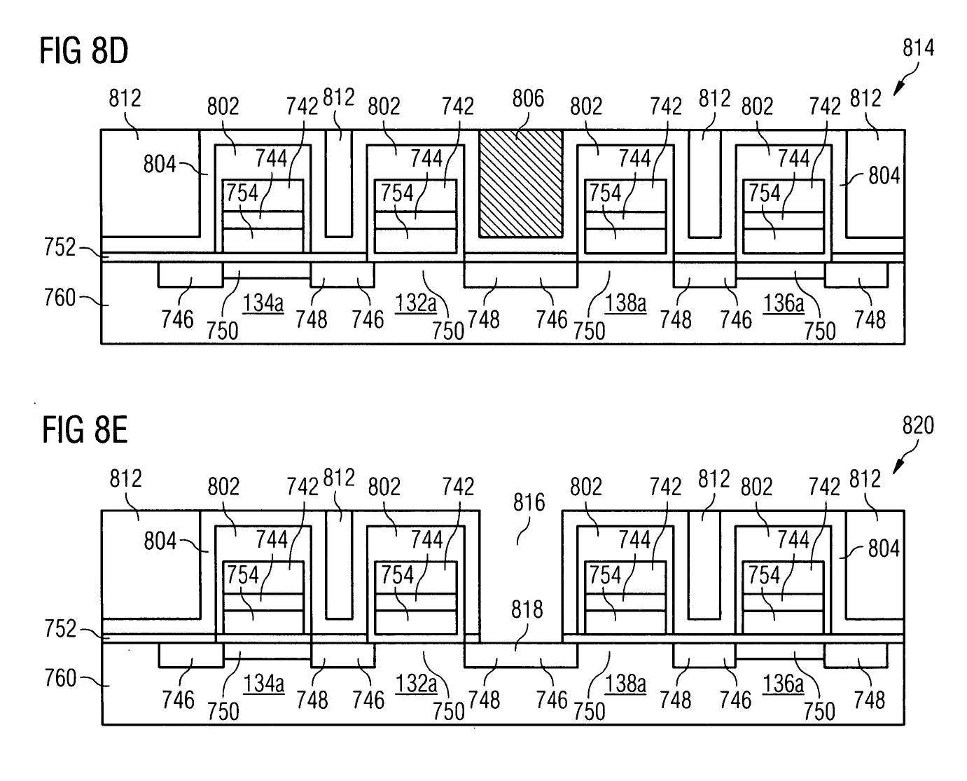

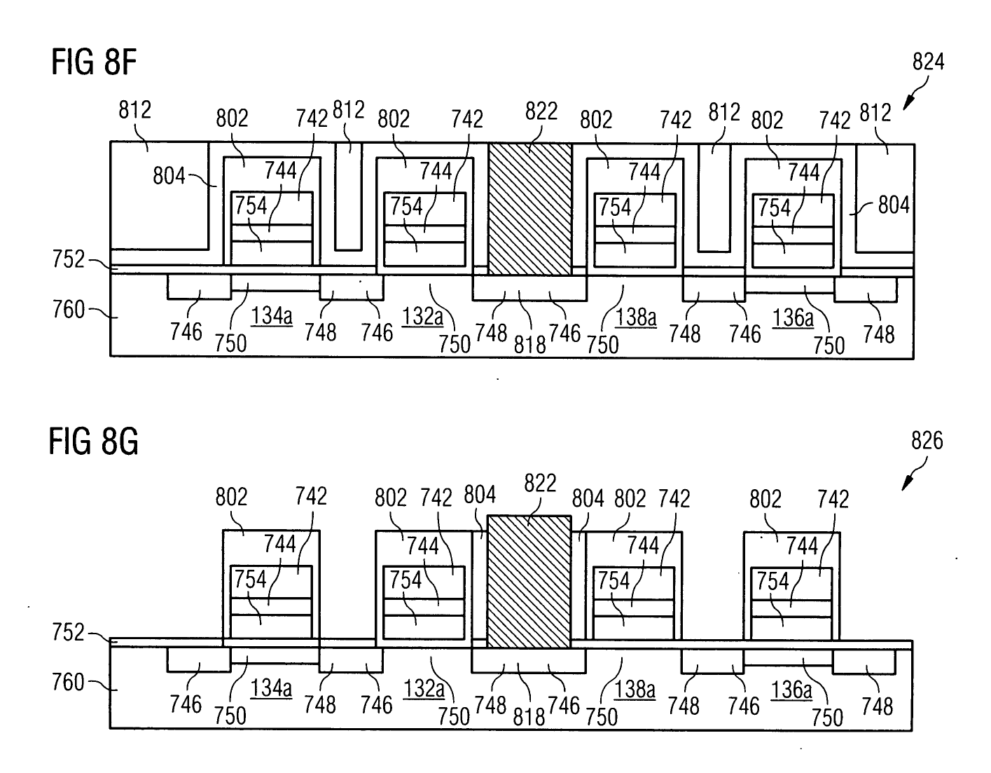

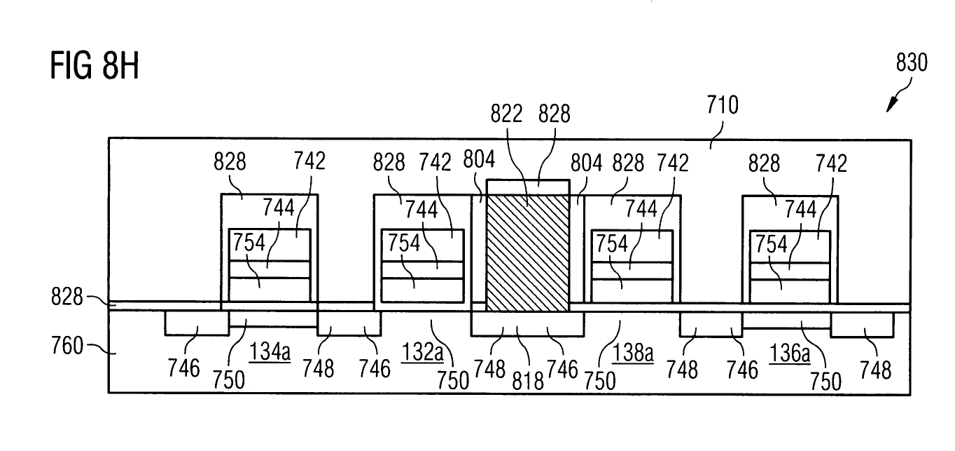

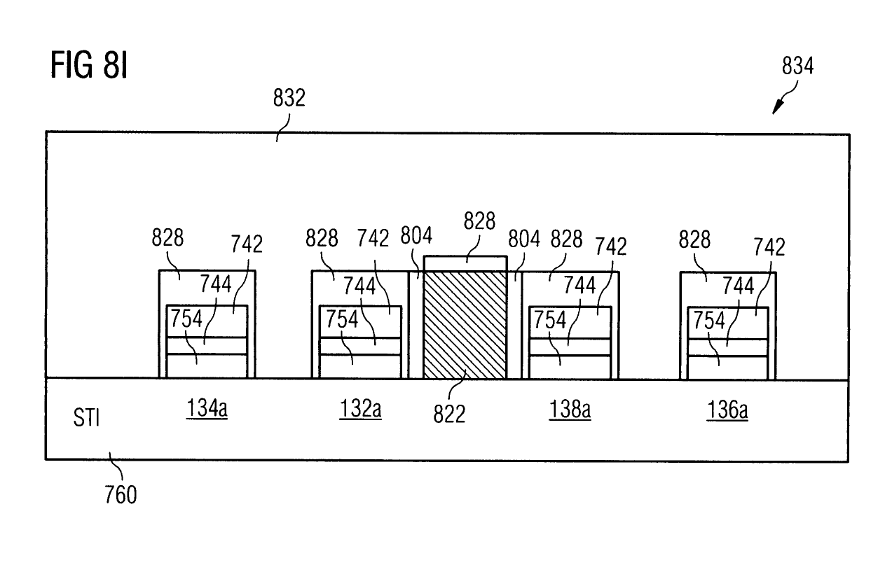

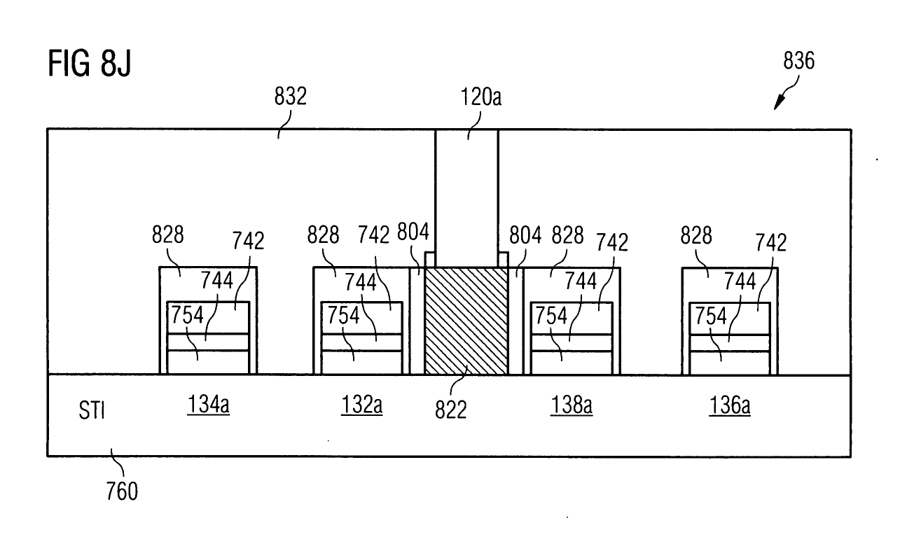

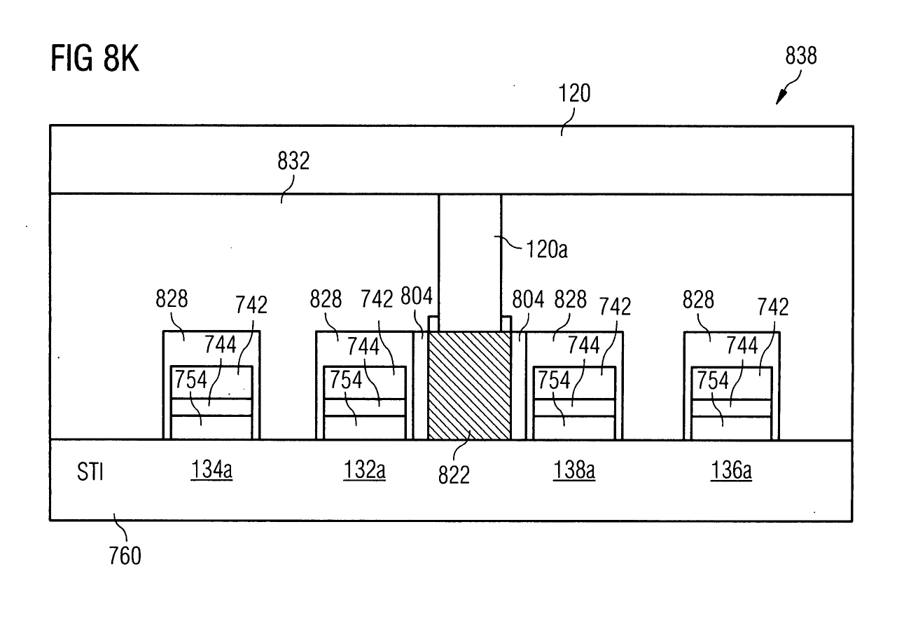

FIG. 8A illustrates a top level view of a common source memory array portion in accordance with FIG. 2 and the present invention, with previously identified features retaining their reference numerals. Bit line interconnect structure 130a is shown coupled to third and fourth memory strings 100c and 100d. Disposed above the active areas of the third and fourth memory strings 100c and 100d are control lines C/L 710 which follow substantially the active areas of the memory strings, as shown in FIG. 7. In this embodiment the control lines 710 provide coupling to the word lines within each of the cells, the voltage difference between the control line 710 and the word line within a particular cell provides a reduced thickness for the cell's dielectric layer between the cell's floating gate and word line to provide lower operating programming and erase voltages. The first bit line interconnect 130a includes input select gates 132a, 134a, 136a, and 138a, and a contact 120a for the first bit line 120 (not shown) which extends substantially in parallel (above, below, or coplanar with) with the third and fourth memory strings 100c and 100d. Third and fourth memory cell strings 100c and 100d are coupled to output select gates 136b and 138b, which are coupled to the second common source/drain line 210b. The first and second memory cell strings are outside the drawing above the first bit line interconnect 130a.

Input select gate control signals 132c, 134c, 136c and 138c are provided to control input select gates 132a, 134a, 136a, and 138a, and output select gate control signals 136d and 138d provide control signals for output select gates 136b and 138b and 136f and 138f. In one embodiment, two of the input select gates, e.g., the second and third string input select gates 134a and 136a, are configured as through connections (either by biasing conditions, or by physical structure), and the remaining two input select gates, e.g., the first and fourth string input select gates 132a and 138a are configured as switches. In a particular embodiment, each of the input select gates 132a-138a are formed as field effect transistors, with two of the input select gates implanted to operate as through connections. An exemplary embodiment of this process is further described below. The second bit line interconnect 130b includes input select gates 132e, 134e, 136e, and 138e, and a contact 120b for the second bit line.

In a specific embodiment, input select gates 132e, 134e, 136e and 138e are configured similarly as the input select gates of the first bit line interconnect 130a. In alternative embodiment, the connection scheme may differ, e.g., the first bit line interconnect 130a may employ the first and fourth select gates as through connections, and the second bit line interconnect 130b implement the second and third input select gates as through connections.

In a particular embodiment, the active areas forming the memory strings 100c, and 100d are 50 nm wide, and separated by 50 nm spacing. In some embodiments, the gate length of the select gates may be longer due to their higher operating voltage in comparison to the memory cells. The cell area size for each of the select gates, bit line contact, and source line contact may be in the order of 4F2. Cross-sectional views AA and BB of the array portion in various states of manufacture are presented in FIGS. 8B-8H and FIGS. 8I-8K, below.

As shown in FIG. 8A, in one embodiment of the invention, the select transistors do not have an isolated floating gate region. The floating gate region and the control gate region are electrically connected to each other.

FIGS. 8B-8H illustrate cross-sectional view AA (as indicated in FIG. 8A) of the common source memory array portion in various states of manufacture in accordance with the present invention. The view is a cross-sectional view in the current flow direction through the memory cells, the cross-section being taken through the control line C/L 710 which is formed adjacent to a bit line 120, and four select gates, e.g., input select gates 132a, 134a, 136a, and 138a are shown. FIGS. 8B-8H depict cross-sectional views of four cells 132, 134, 136, 138 to more clearly illustrate the invention, although the cross-sectional views of only two memory cells would be shown in the view AA indicated in FIG. 8A. The cell structure illustrated is a Flash floating gate architecture, but as noted above, memory cells of different technologies and/or architectures may be used instead. In the embodiment shown, the four select gates, e.g., input select gates 132a, 134a, 136a, and 138a have a similar structure as the memory cells in the memory cell strings 100a, 100b, 100c, 100d, although the four select gates are configured as through connections (e.g., as normally-on field effect transistor) or as a switch, as described above. Therefore, in FIGS. 8B-8H, the same reference numbers are used for the elements of the four select gates, e.g., input select gates 132a, 134a, 136a, and 138a, as for the transistor arrangement 700 in FIG. 7.

Initially, the gate stacks of the input select gates 132a, 134a, 136a and 138a are formed concurrently with the gate stacks of the memory cells. During this process the active regions 750 of the select gates, which are to form through connections (e.g., 134a and 136a), are implanted in the carrier 760, with a material that renders the active regions 750 substantially conductive. Arsenic is used as an implant material in one embodiment, although other materials may be used in alternative embodiments. The arsenic implant is carried out in the beginning in the so-called Vt implant of the active regions of the transistors to be formed. In an alternative embodiment of the invention, an antimon implant may be used instead of the arsenic implant.

In one embodiment of the invention, the gates stacks are formed by depositing a tunnel dielectric layer 752, e.g., made of an oxide such as silicon oxide on or above at least a part of the, e.g., on or above the entire, main processing surface of the carrier 760. Next, an electrically conductive layer from which the floating gate regions 754 will be formed, e.g., made of poly-silicon, is deposited on or above at least a part of the, e.g., on or above the entire, tunnel dielectric layer 752. Then, a further dielectric layer, e.g., made of an oxide such as silicon oxide or aluminum oxide, from which the control gate dielectric region 744 will be formed, is deposited on or above at least a part of the, e.g., on or above the entire, electrically conductive layer. Next, a further electrically conductive layer from which the control gate regions 742 and the word lines will be formed, e.g., made of poly-silicon, is deposited on or above at least a part of the, e.g., on or above the entire, further dielectric layer. Next, a silicon oxide layer 802 is deposited on top of the control gate regions 742. In a following process, the gate stacks are formed by patterning the electrically conductive layer, the further dielectric layer and the further electrically conductive layer. This is carried out using a lithographic process and a corresponding etching process. Then, the sidewall silicon oxide is deposited. Then, using an anisotropic etch process such as reactive ion etching (RIE), gate stack sidewall spacers are formed by anisotropically etching the silicon oxide between the gate stacks. Thus, the gate stacks are fully encapsulated in oxide. Then, a nitride (e.g., silicon nitride) layer 804 is deposited on the patterned encapsulated structure of the gate stacks. Furthermore, a layer 806 of electrically conductive material (doped or undoped) such as poly-silicon, is deposited on the nitride layer 804, also in the cavities between the gate stacks. The layer 806 of electrically conductive material is then planarized, e.g., by means of a CMP with stop on the upper surface of the nitride layer 804 above the gate stacks. FIG. 8B illustrates the resulting structure 808.

Then, the bit line interconnects 130a to 130d are formed using a lithographic process which will be described in more detail below. A hardmask layer, e.g., made of silicon oxide or carbon, is deposited on or above the upper surface of the structure 808 of FIG. 8B. Then, a photoresist layer is deposited on or above the hardmask layer. The photoresist layer is illuminated and developed, thereby patterning the photoresist layer. In this way, portions of the hardmask layer are exposed. It should be noted that the portion of the hardmask layer above the portion of the layer 806 of electrically conductive material that is located between the select gates 132a and 138a will not be exposed and thus will not be removed. The patterning of the photoresist layer is carried out such that the portions of the hardmask layer above the portion of the photoresist layer that are located between the other select gates (e.g., between the input select gates 134a and 132a and between the select gates 138a and 136a), are exposed. Then, the exposed portions of the hardmask layer are etched, thereby exposing those portions of the layer 806 of electrically conductive material that are located below the etched portions of the hardmask (e.g., between the select gates 134a and 132a). Next, the exposed portions of the layer 806 of electrically conductive material (e.g., made of poly-silicon), are removed, e.g., using a wet etch process or using a dry etch process. Thus, only the portion of the layer 806 of electrically conductive material between the select gates 132a and 138a will not be removed. FIG. 8C illustrates the resulting structure 810.

Then, a dielectric layer 812, e.g., made of an oxide, e.g., silicon oxide, is deposited on or above the structure 810 of FIG. 8C. The dielectric layer 812 is partially removed e.g., using a CMP process with stop on the upper surface of the nitride layer 804 above the gate stacks. FIG. 8D illustrates the resulting structure 814.

Next, the exposed remaining portion of the layer 806 of electrically conductive material between the select gates 132a and 138a, which descriptively serves as a sacrificial layer (e.g., sacrificial poly-silicon layer), is removed, e.g., using a wet etch process or a dry etch process, thereby forming a trench 816. Then, the bottom of the trench 816, which is formed by a portion of the tunnel dielectric layer 752 and the nitride layer 804 is removed by means of a spacer etching, thereby exposing an interconnect region 818 of the carrier 760 between the second source/drain region 748 of the input select gate 132a and the first source/drain region 746 of the select gate 138a. Additionally, arsenic or another similar doping material is implanted into the bottom of the interconnect region 818 to form a conductive junction coupled to the source/drain junctions of the adjacent select gates (e.g., 132a and 138a). The implantation of the doping atoms, such as arsenic, is carried out with a doping concentration in the range of about 1019 cm⁻³ to about 1020 cm⁻³. The resulting structure 820 is illustrated in FIG. 8E.

Next, poly-silicon 822 is deposited within the trench 816, e.g., through a doped in situ chemical-vapor deposition (CVD) process, the poly-silicon layer 822 subsequently planarized level with the nitride layer 804 of the stack structures through CMP. The resulting structure 824 is illustrated in FIG. 8F.

Then, the dielectric layer 812, e.g., made of an oxide, e.g., silicon oxide, of the structure 824 of FIG. 8F is removed by means of a wet etch process. Furthermore, the nitride layer 804 is removed by means of a wet etch process except for the portions that are between the poly-silicon layer 822 and the select gates 132a and 138a, respectively. The nitride and oxide layers 804, 812 adjacent to the through connection select gates (e.g., 134a and 136a) are thus etched, thereby forming an interconnect post 822 to which the bit line will contact in the view BB as will be described in more detail below. The resulting structure 826 is illustrated in FIG. 8G.

Next, the oxide layers, that is the exposed portions of the silicon oxide layer 802 and the exposed portions of the tunnel dielectric layer 752 are removed by means of a wet etch process, followed by an oxidization process of the gate stacks, thereby forming a “fresh” high quality oxide layer 828 encapsulating the gate stacks and covering the exposed surface of the carrier 760 and of the poly-silicon layer 822. The top surface of the interconnect post 822 is isolated from the control line C/L 710 by the oxide layer 828. Control line C/L 710 coupling to the gate junction of each memory cell in the NAND string is deposited, planarized, masked and etched to form the NAND strings coupling to the select gates of the bit line interconnect 130. Then, the photo resist layer used for previous masking and etching is removed. The resulting structure 830 is illustrated in FIG. 8H.

FIGS. 8I-8K illustrate cross-sectional view BB (as indicated in FIG. 8A) of the common source/drain memory array portion in various states of manufacture in accordance with the present invention. As shown in FIG. 8A, the view is taken across the bit line contact 120a, which is formed between (and possibly vertically offset from) adjacent control lines 710. FIGS. 8I-8K depict cross-sectional views of four select gates, 132a, 134a, 136a, and 138a to more clearly illustrate the invention, although the cross-sectional views of only two select gates would be shown in view BB indicated in FIG. 8A. The cell structure illustrated is a Flash floating gate architecture, but as noted above, select gates of different technologies and/or architectures may be used instead.

The process begins after the point in construction shown in FIG. 8H, and continues with the deposition of the oxide layer 832, e.g., silicon oxide layer, the oxide layer 832 then being planarized through a CMP process. FIG. 8I illustrates the resulting structure 834.

Subsequently, the oxide layer 832 is etched to form a trench within which the bit line interconnect 120a is formed in contact with the interconnection post 822. In a particular embodiment, tungsten is used as the material to form the bit line contact 120a, although other materials may be used in alternative embodiments, e.g., doped poly-silicon. The resulting structure 836 is shown in FIG. 8J.

Next, a bit line (e.g., 120) is formed in contact with the bit line contact 120a, the bit line metal patterned and etched to its final shape. In a particular embodiment, the bit line 120 is formed from aluminum, although other metals may be used in other embodiments. The resulting structure 838 is shown in FIG. 8K.

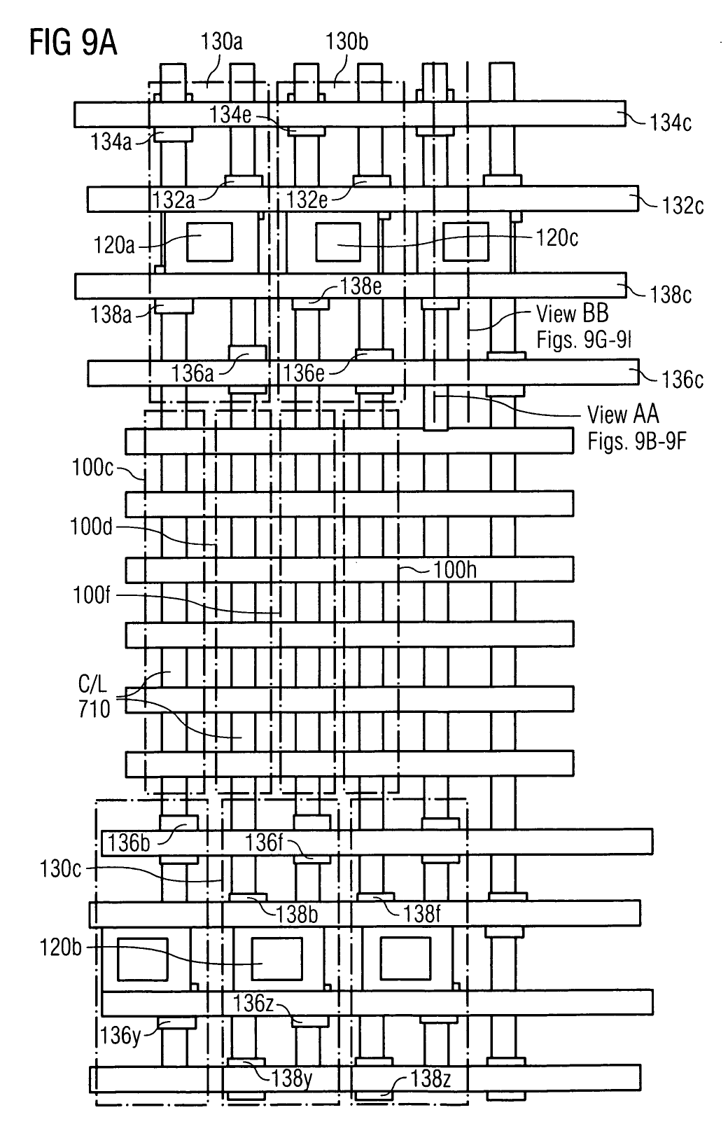

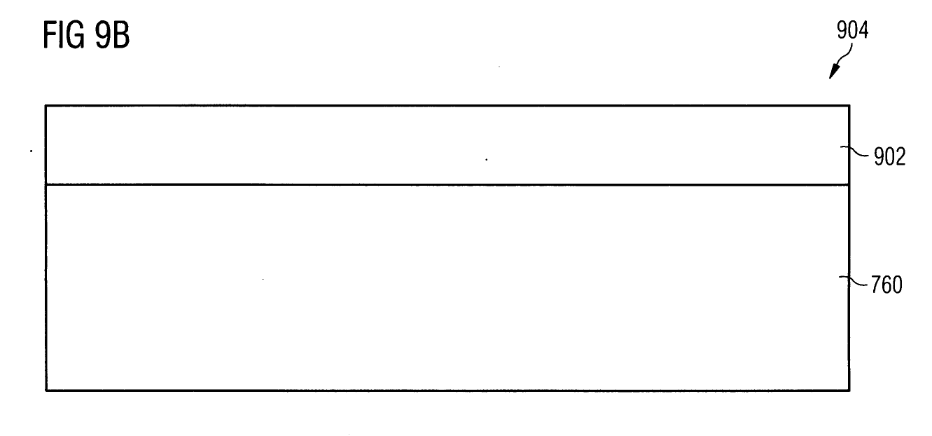

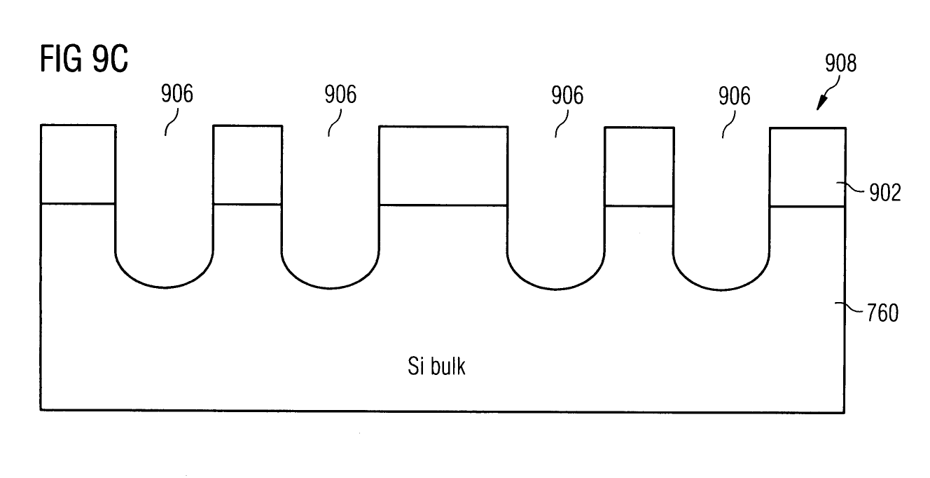

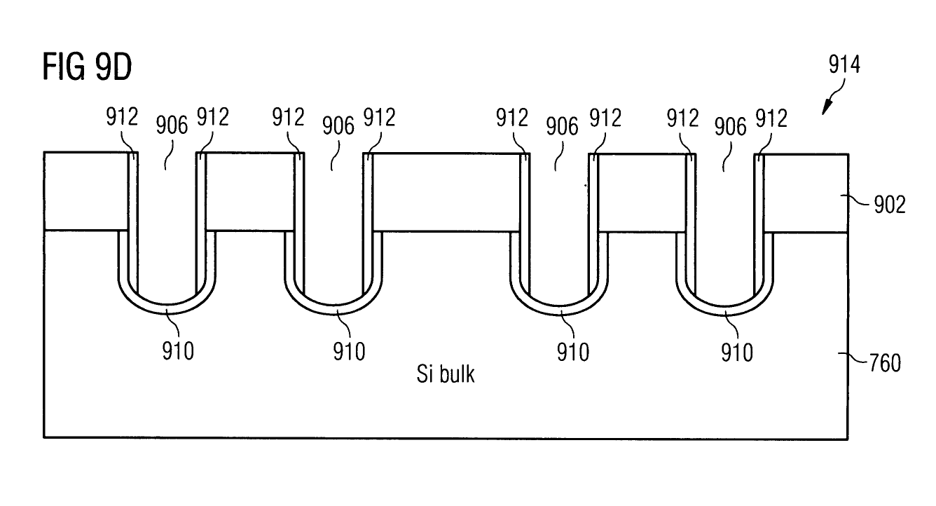

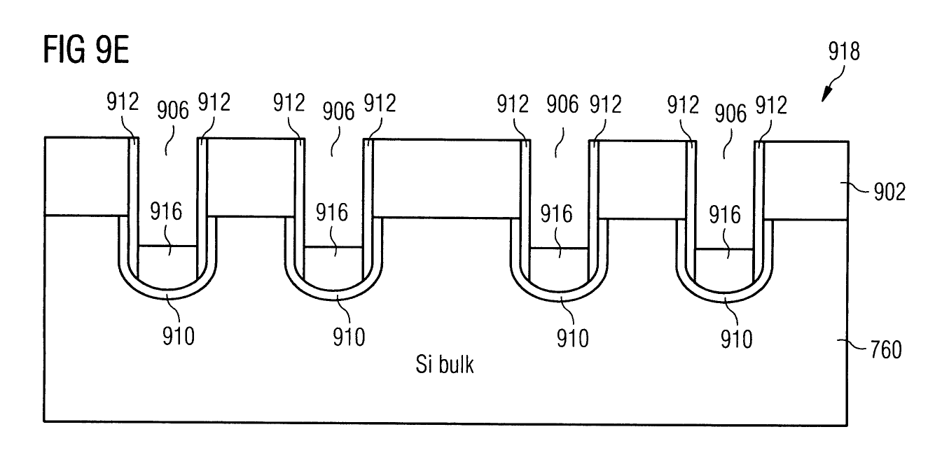

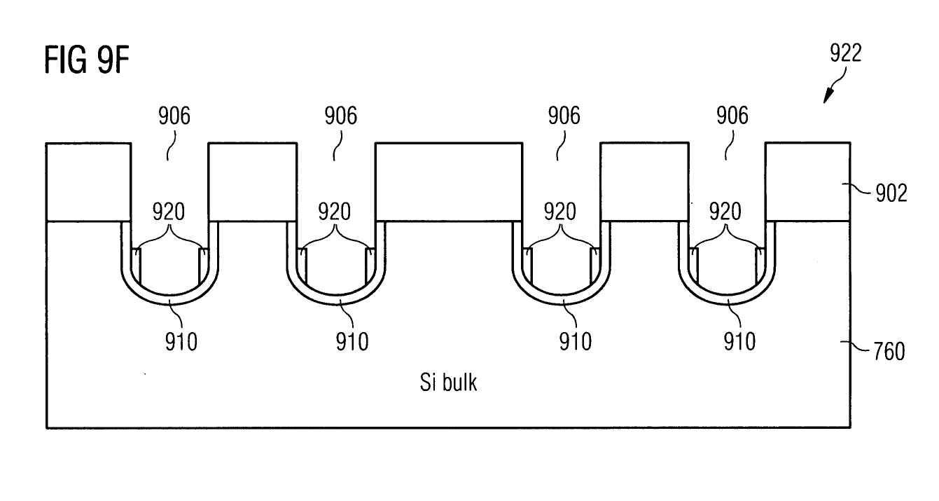

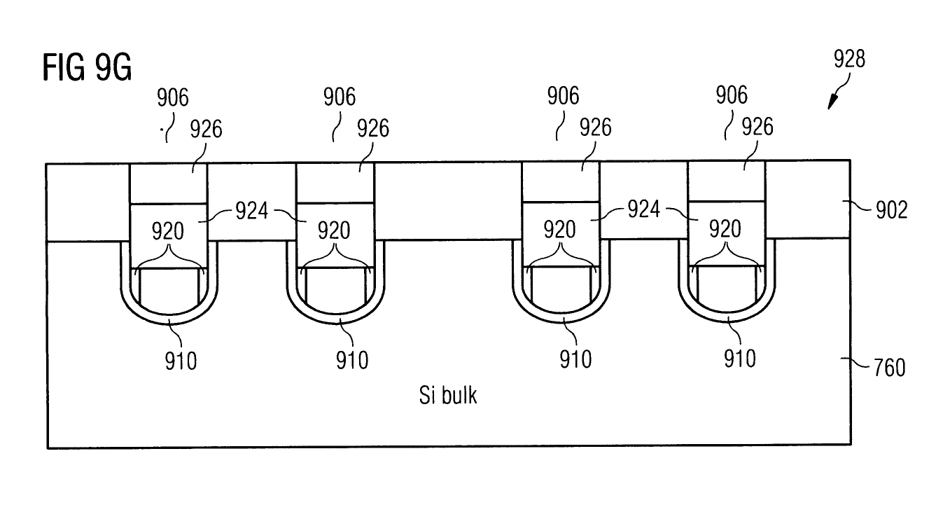

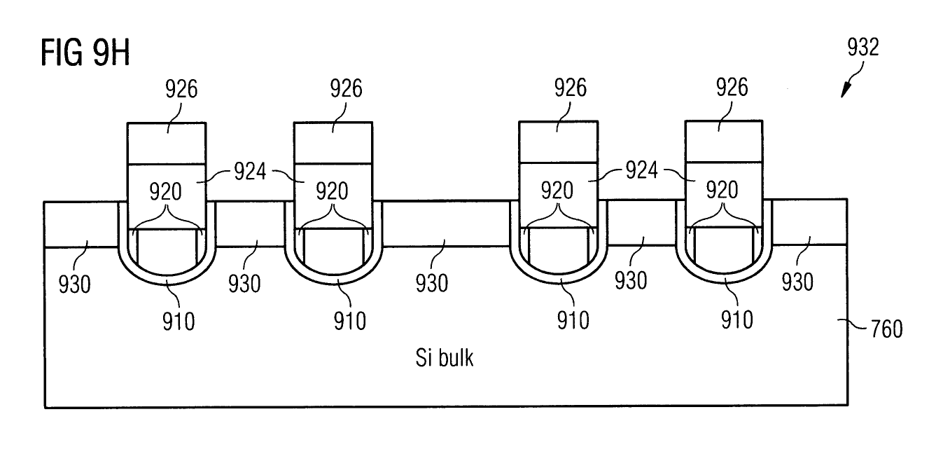

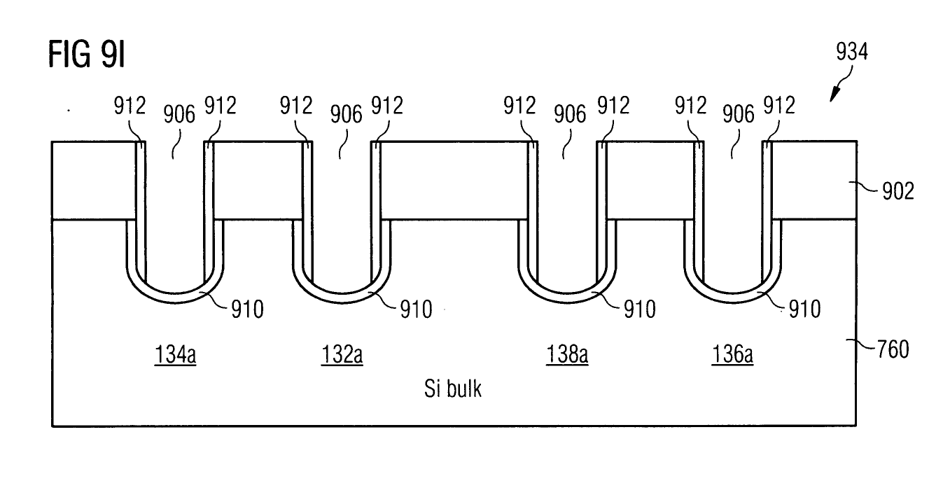

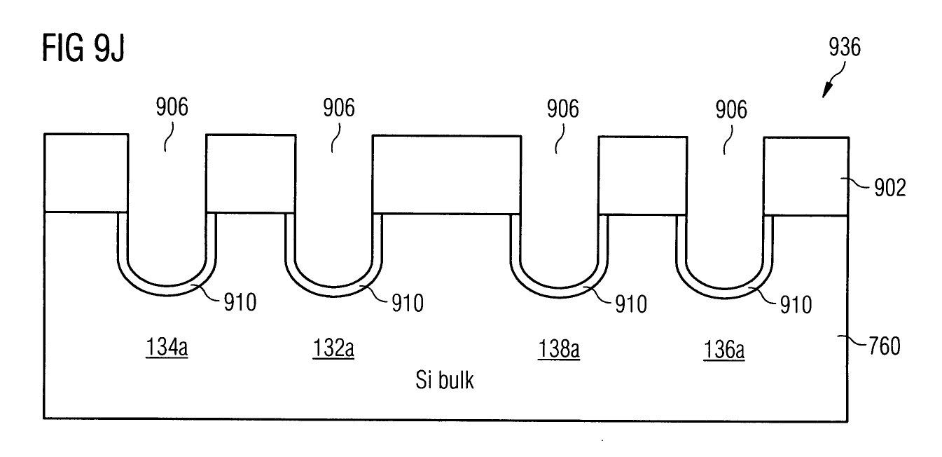

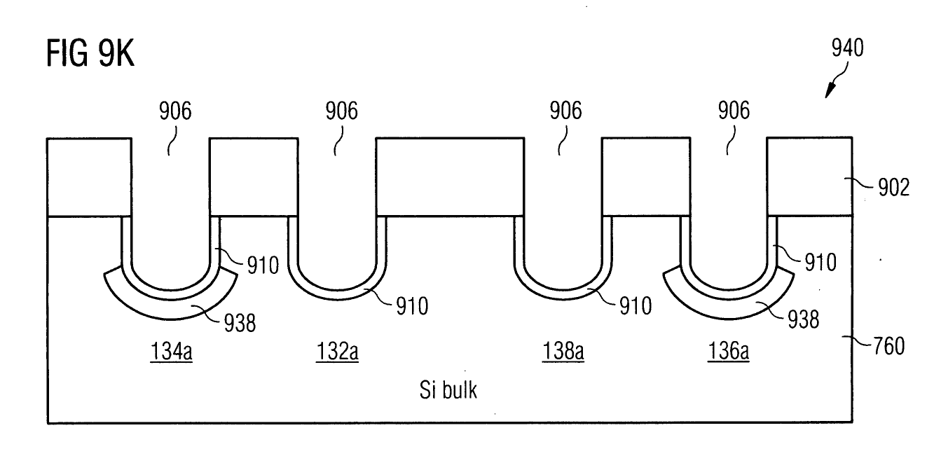

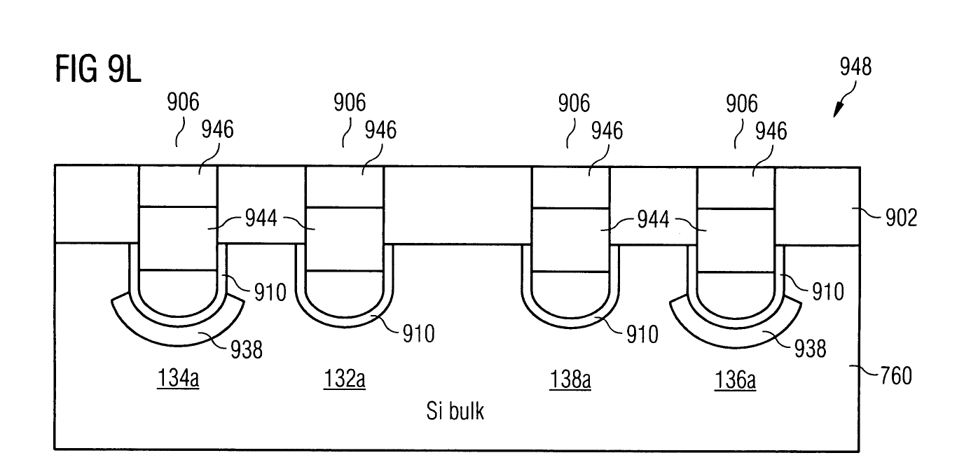

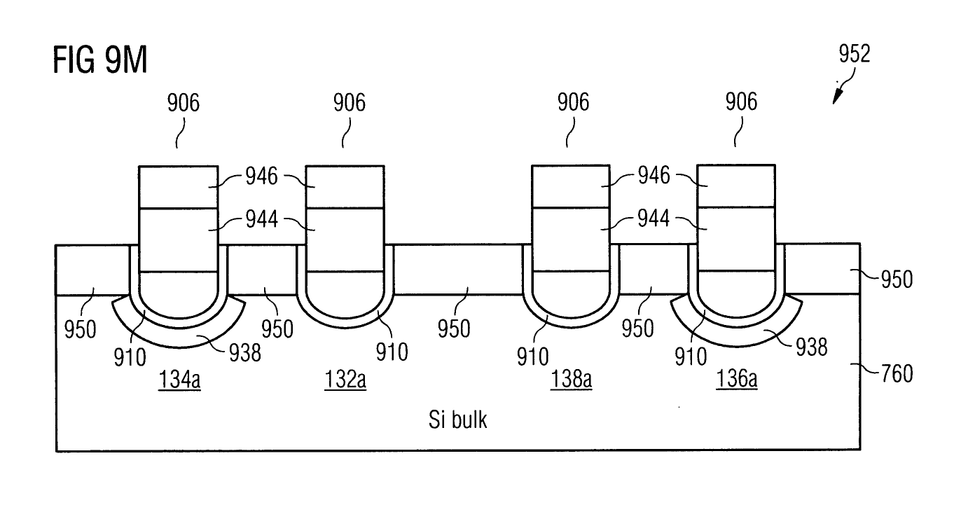

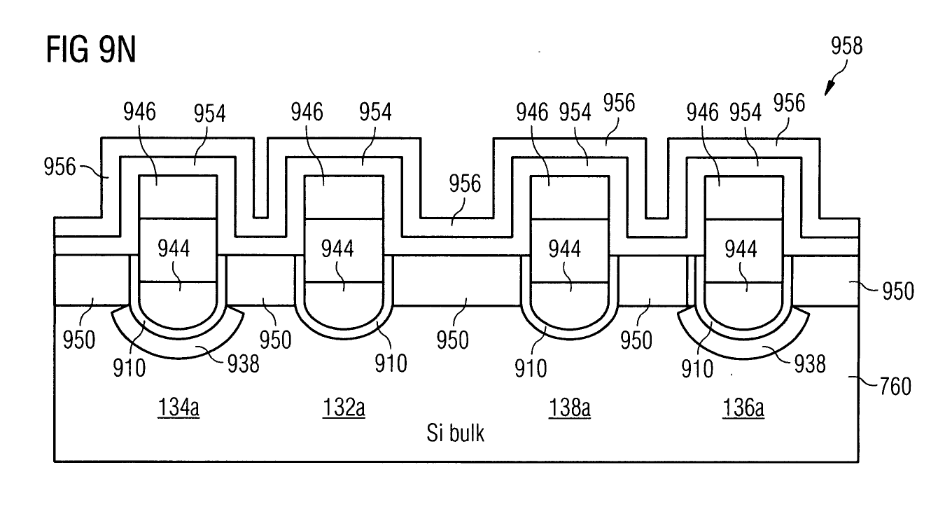

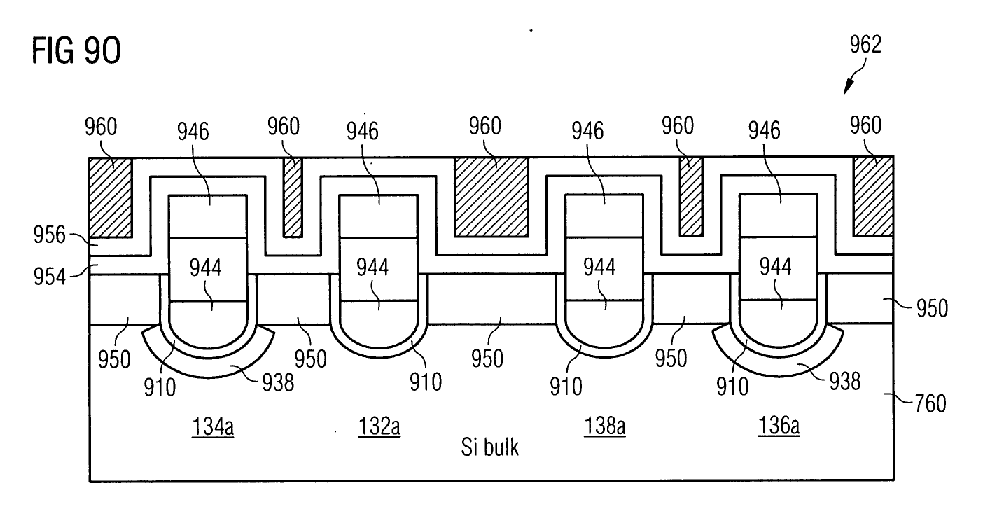

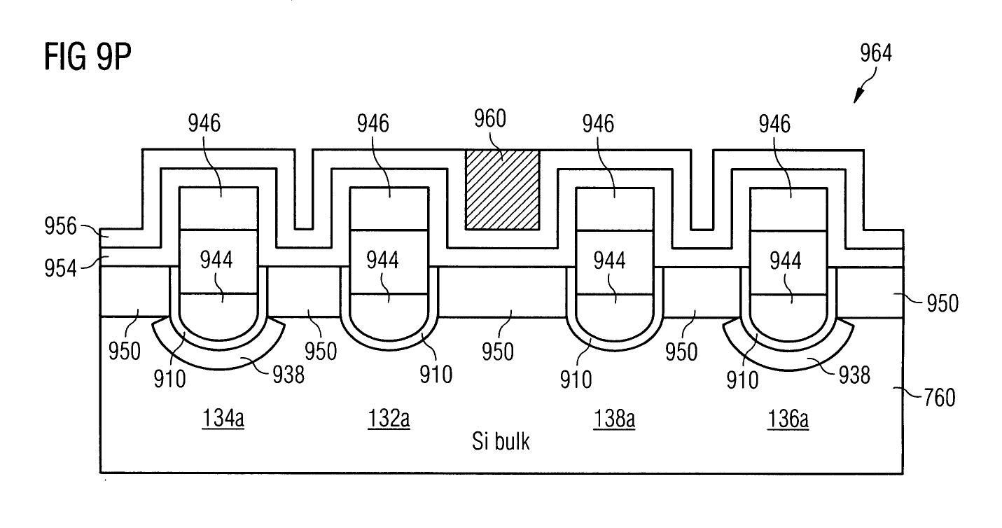

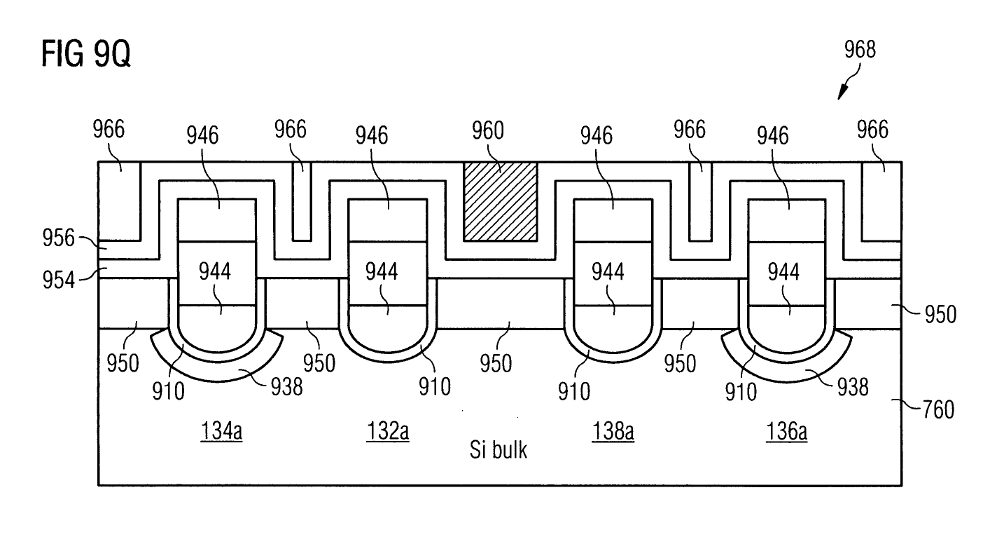

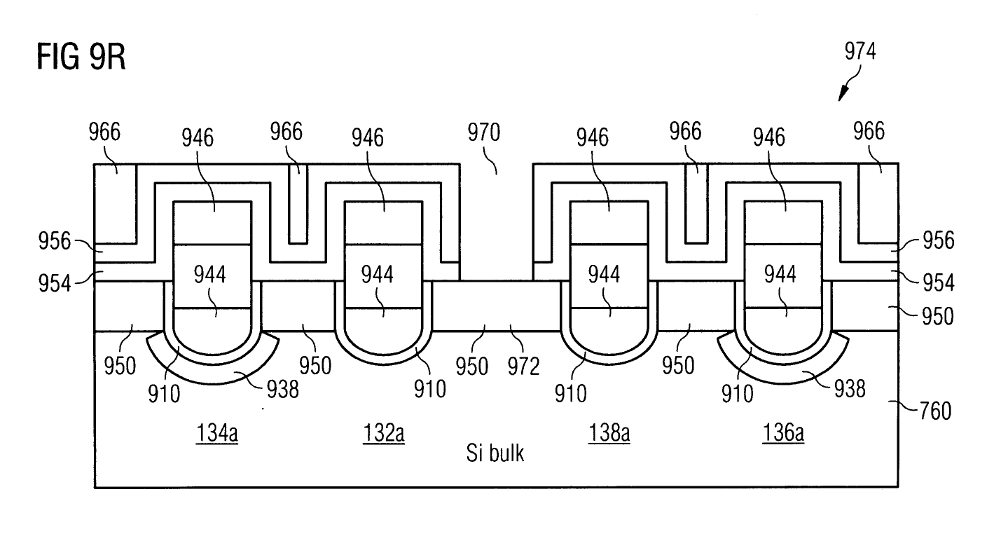

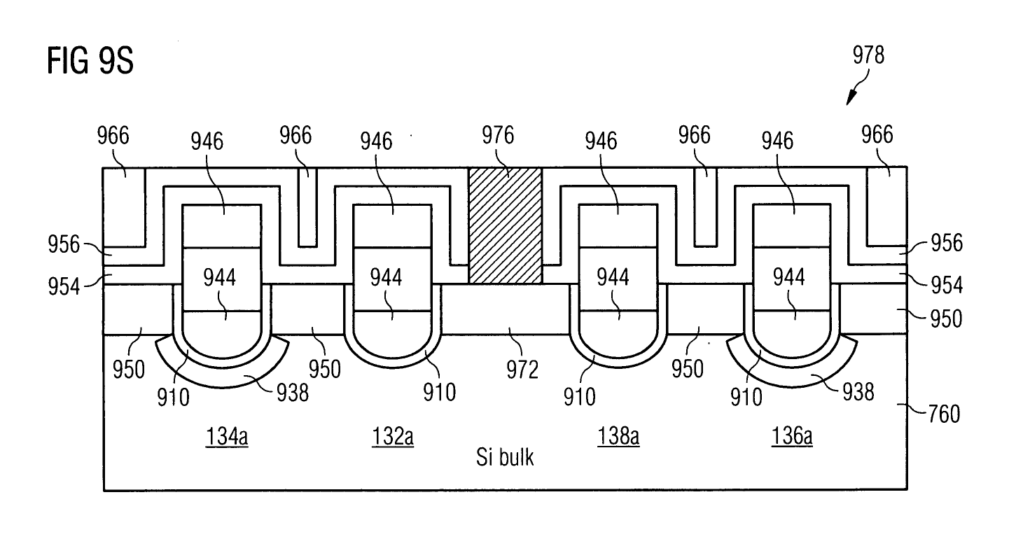

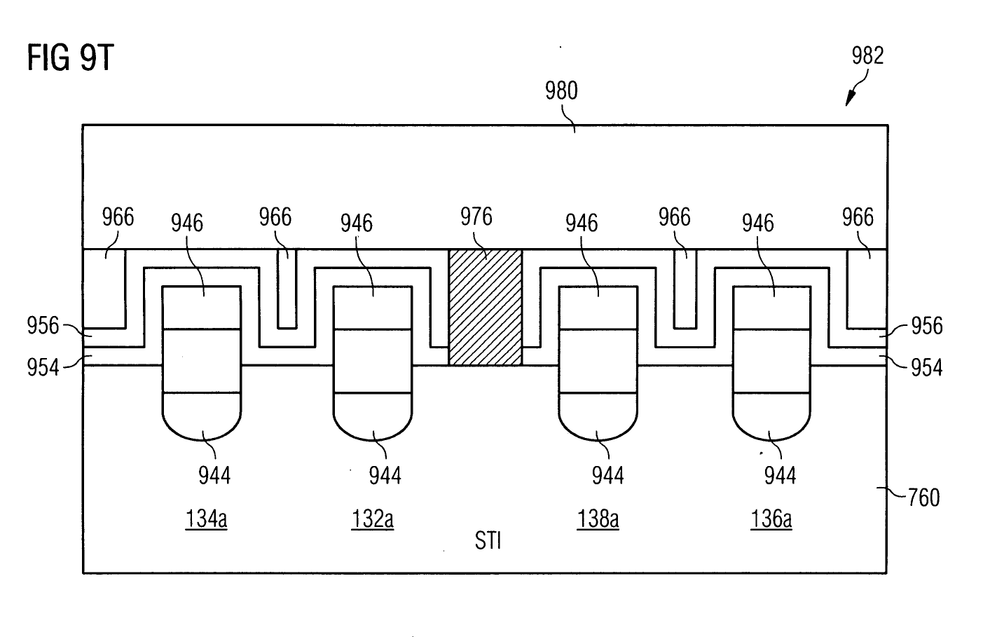

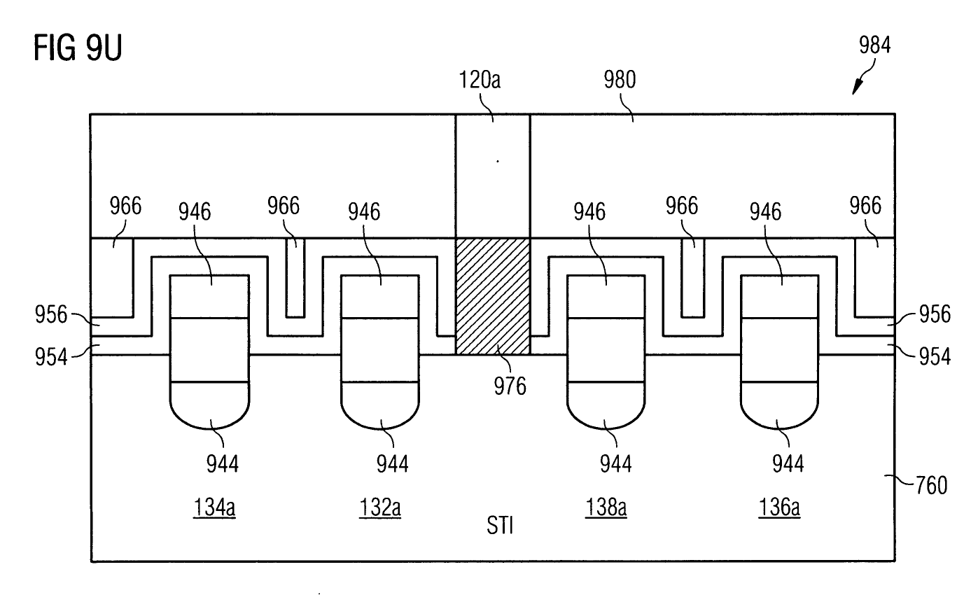

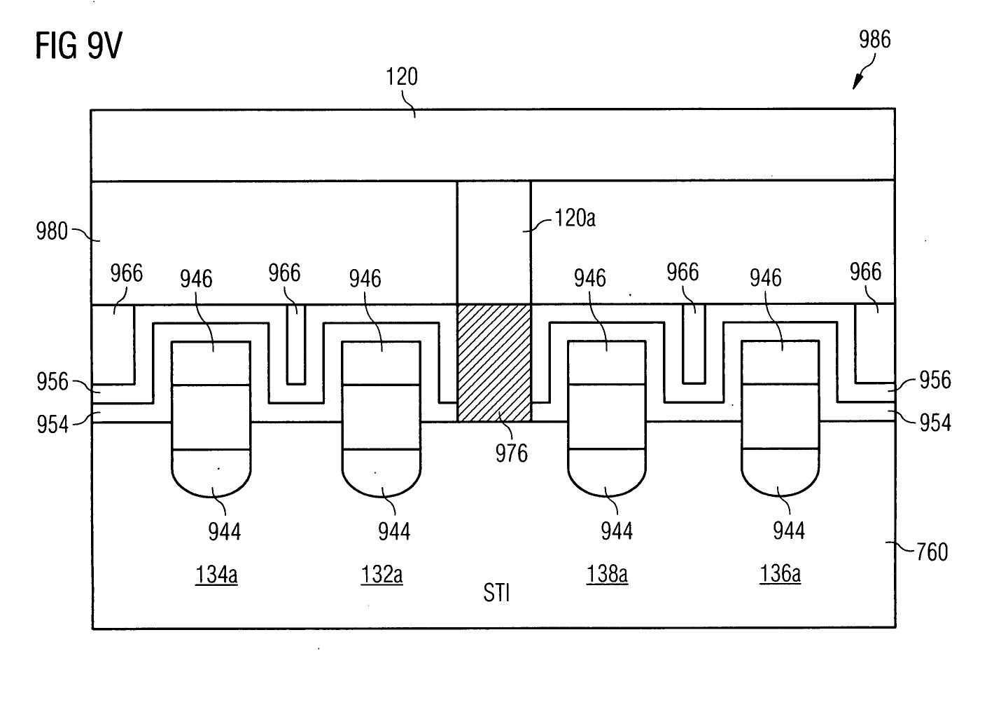

FIG. 9A illustrates a top level view of a virtual ground memory array portion in accordance with FIG. 3 and the present invention, with previously identified features retaining their reference numerals.

Disposed above the active areas of the third and fourth memory strings 100c and 100d are control lines C/L 710 which follow substantially the active areas of the memory strings, as shown in FIG. 7. In this embodiment the control lines 710 provide coupling to the word lines within each of the cells, the voltage difference between the control line 710 and the word line within a particular cell providing a reduced effective thickness for the cell's dielectric layer between the cell's floating gate and word line to provide lower operating programming and erase voltages. The first bit line interconnect 130a includes input select gates 132a, 134a, 136a, and 138a, and a contact 120a for the first bit line 120 (not shown) which extends substantially in parallel (above, below, or coplanar with) with the third and fourth memory strings 100c and 100d. Third and fourth memory cell strings 100c and 100d are coupled to output select gates 136b and 138b. The third interconnect 130c is shown as bridging between the fourth and sixth memory strings 100d and 100f, providing each with a bit line voltage (from bit line 120b) at the output select gates for the fourth and sixth strings 100d and 100f when activated. The pattern is repeated to form an array of memory cells, as shown and described herein.

In a particular embodiment, the active areas forming the memory strings 100c, 100d, 100f and 100h are 50 nm wide, and separated by 50 nm spacing. The cell area size for each of the select gates, bit line contact and source line contact can be as small as 4F2. Cross-sectional views AA and BB of the array portion in various states of manufacture are presented in FIGS. 9B-9S and 9T-9V, below.

FIGS. 9B-9S illustrate cross-sectional view AA (as indicated in FIG. 9A) of the virtual ground memory array portion in various states of manufacture in accordance with the present invention. As shown in FIG. 9A, the view is taken across the control line 710 formed between (and possibly vertically offset from) adjacent bit line contacts. FIGS. 9B-9H depict cross-sectional views of memory cells of the memory cell string. FIGS. 9B-9R depict cross-sectional views of memory cells (FIGS. 9B-9H) and of four select gates 132a, 134a, 136a, and 138a (FIGS. 9I-9R) to more clearly illustrate the invention, although the cross-sectional views of only two select gates would be shown in view BB indicated in FIG. 9A. The cell structure illustrated is a Flash recessed gate architecture. As noted above memory cells of different technologies and/or architectures may be used instead.

Initially, after having formed the shallow trench isolations (STI) in the carrier 760, the hardmask layer used for the formation of the shallow trench isolations is removed, e.g., by means of wet etching or by means of dry etching. Then, an oxide layer 902, e.g., made of silicon oxide, is deposited on the upper surface of the carrier 760. The resulting structure 904 is shown in FIG. 9B.

Then, trenches 906 for the select gates 132a, 134a, 136a and 138a, wherein the trenches are formed through the oxide layer 902 extending into the carrier 760. The trenches 906 have a curved bottom surface. In order to form the trenches 906, a lithographic process is carried out including forming a hardmask layer on or above the upper surface of the oxide layer 902, forming a photoresist layer on or above the hardmask layer, illuminating the photoresist layer with light in accordance with the structure of the memory cells (e.g., memory transistors) to be formed. The photoresist layer is then patterned and the thus exposed portions of the hardmask layer are etched, thereby exposing portions of the upper surface of the oxide layer 902, in which the trenches 906 are to be formed. Next, the photoresist layer is removed (e.g., stripped) and the oxide layer 902 and portions of the carrier 760 (e.g., made of silicon) are etched using the hardmask layer as etching mask. The resulting structure 908 is shown in FIG. 9C.

Next, the exposed portions of the carrier portions of the trenches 906 are oxidized, thereby forming U-shaped oxide layers 910 on the sidewalls and the bottom of the trenches 906. Then, a nitride layer is deposited followed by an oxidation process to form an Oxide Nitride Oxide layer 912 (in the following also referred to as nitride/oxide spacers 912) at the sidewall of the trenches 906. Next, an anisotropic etch process is carried out, e.g., by means of reactive ion etching (RIE), thereby forming nitride/oxide spacers 912 on the sidewalls of the trenches 906. The resulting structure 914 is shown in FIG. 9D.

Then, the trenches 906 are filled and possibly overfilled with electrically conductive material such as poly-silicon. The overfilling material is removed using a CMP, for example. Subsequently, the electrically conductive material in the trenches is partially removed again, using a recess etch process, thereby forming a electrically conductive material layer 916 in the lower region of the trenches 906. The resulting structure 918 is shown in FIG. 9E.

In a following process, in one embodiment of the invention, the top oxide is removed, e.g., by means of a wet etch process. Then, the nitride/oxide spacers 912 are partially removed by means e.g., of a wet etch process, with stop on the level of the upper surface of the electrically conductive material layer 916. Then, the electrically conductive material layer 916 in the trenches 906 is completely removed. Thus, shortened nitride spacers 920 are formed within the trenches 906, the shortened nitride spacers 920 extending up to the height of the removed electrically conductive material layer 916. The resulting structure 922 is shown in FIG. 9F.

Then, in one embodiment of the invention, a top dielectric layer is deposited (e.g., Al₂O₃). In one embodiment of the invention, the trenches 906 are again filled and possibly overfilled with an electrically conductive material such as poly-silicon. Furthermore, a recess etch of the electrically conductive material is carried out such that the electrically conductive material is partially removed in the trenches 906, thereby forming a further electrically conductive material layer 924. Next, the remaining portions of the trenches 906 are filled and possibly overfilled with tungsten silicide. The overfilling tungsten silicide is removed, e.g., by means of CMP, thereby forming tungsten silicide layers 926 in the trenches 906. Other electrically conductive materials and other silicides may be used in alternative embodiments of the invention. The resulting structure 928 is shown in FIG. 9G.

Next, the oxide layer 902 is etched in accordance with the desired pattern of the transistors to be formed, with stop on the upper surface of the carrier 760. In the following process, the exposed portions of the carrier 760 are implanted with n-type doping atoms (for n-type memory cells) (n+-implant), although in an alternative embodiment, in which the memory cells should be formed as p-type memory cells, the exposed portions of the carrier 760 are implanted with p-type doping atoms (p+-implant). The implantation is carried out using the remaining portions of the oxide layer 902 as implantation mask. Thus, source/drain regions 930 of the memory cells of the memory cell strings are formed. The resulting structure 932 is shown in FIG. 9H.

Referring now to FIG. 9I, in order to form the four select gates 132a, 134a, 136a, and 138a, after having formed the trenches in the same manner as described with reference to FIGS. 9C and 9D, including oxidizing the exposed portions of the silicon material of the carrier 760 and forming the nitride spacers 912, the trenches 906 are filled and possibly overfilled with electrically conductive material such as poly-silicon. The overfilling poly-silicon is removed by means of a CMP process. Then, a recess poly-silicon etch is carried out followed by a formation of a recessed gate structure using lithographic processes. Then, the remaining electrically conductive material such as poly-silicon is completely removed, e.g., etched. Then, the photoresist used for the lithographically formed recessed gate structure is removed (e.g., stripped). Then, a top oxide layer (e.g., nitride) is etched, e.g., by means of wet etching. The resulting structure 934 is shown in FIG. 9I.

Furthermore, the nitride/oxide spacers 912 are removed, e.g., by means of wet etching. The resulting structure 936 is shown in FIG. 9J.

Next, a lithographic process of forming the normally-on select gates (e.g., 134a and 136a) is carried out (in other words, forming the through connections), e.g., by covering the trenches 906 disposed above those select gates which should be formed as switches with photoresist. The exposed bottom regions of the trenches 906 of the select gates to be formed as through connections (e.g., 134a and 136a) are subject to an implantation of doping atoms such as arsenic. However, other materials may be used in alternative embodiments for the implant. Thus, implanted regions 938 are formed in the bottom regions of the trenches 906 of the select gates to be formed as through connections (e.g., 134a and 136a) below the bottom oxide layer 910. The resulting structure 940 is shown in FIG. 9K.

Then, in one embodiment of the invention, the trenches 906 are again filled and possibly overfilled with an electrically conductive material such as poly-silicon. Furthermore, a recess etch of the electrically conductive material is carried out such that the electrically conductive material is partially removed in the trenches 906, thereby forming a further electrically conductive material layer 944. Next, the remaining portions of the trenches 906 are filled and possibly overfilled with tungsten silicide. The overfilling tungsten silicide is removed, e.g., by means of CMP, thereby forming tungsten silicide layers 946 in the trenches 906. Other electrically conductive materials and other silicides may be used in alternative embodiments of the invention. The resulting structure 948 is shown in FIG. 9L.

Next, the hard mask formed by the oxide layer 902 is etched in accordance with the desired pattern of the transistors to be formed, with stop on the upper surface of the carrier 760. In the following process, the exposed portions of the carrier 760 are implanted with n-type doping atoms (for n-type select gates) (n+-implant), although in an alternative embodiment, in which the select gates should be formed as p-type select gates, the exposed portions of the carrier 760 are implanted with p-type doping atoms (p+-implant). The implantation is carried out using the remaining portions of the oxide layer 902 as implantation mask. Thus, source/drain regions 950 of the select gates 132a, 134a, 136a, and 138a are formed. The resulting structure 952 is shown in FIG. 9M.

Then, an oxide layer 954, e.g., made of silicon oxide, is deposited on or above the structure 952 of FIG. 9M. Furthermore, a nitride layer 956, e.g., made of silicon nitride, is deposited on or above the oxide layer 954. The resulting structure 958 is shown in FIG. 9N.

Furthermore, electrically conductive material such as poly-silicon is deposited on or above the structure 958 of FIG. 9N. The conductive material is then partially removed again in order to planarize the structure through CMP with stop on the upper surface of the nitride layer 956, thereby forming an electrically conductive material layer 960. The resulting structure 962 is shown in FIG. 90.

Then, the bit line interconnect is formed using a lithographic process which will be described in more detail below. A hardmask layer, e.g., made of silicon oxide or carbon, is deposited on the upper surface of the structure 962 of FIG. 90. Then, a photoresist layer is deposited on the hardmask layer. The photoresist layer is illuminated and developed, thereby patterning the photoresist layer. In this way, portions of the hardmask layer are exposed. It should be noted that the portion of the hardmask layer above the portion of the layer 960 of electrically conductive material that is located between the select gates 132a and 138a will not be exposed and thus will not be removed. The patterning of the photoresist layer is carried out such that the portions of the hardmask layer above the portion of the layer 960 of electrically conductive material that are located between the other select gates (e.g., between the select gates 134a and 132a and between the select gates 138a and 136a), are exposed. Then, the exposed portions of the hardmask layer are etched, thereby exposing those portions of the layer 960 of electrically conductive material that are located below the etched portions of the hardmask. Next, the exposed portions of the layer 960 of electrically conductive material (e.g., made of poly-silicon), are removed, e.g., using a wet etch process. Thus, only the portion of the layer 960 of electrically conductive material between the select gates 132a and 138a will not be removed. FIG. 9P illustrates the resulting structure 964.

Then, a dielectric layer 966, e.g., made of an oxide, e.g., silicon oxide, is deposited on or above the structure 964 of FIG. 9P. The dielectric layer 966 is partially removed e.g., using a CMP process with stop on the upper surface of the nitride layer 956 above the gate stacks. FIG. 9Q illustrates the resulting structure 968.

Next, the exposed remaining portion of the layer 960 of electrically conductive material between the select gates 132a and 138a, which clearly serves as a sacrificial layer (e.g., sacrificial poly-silicon layer), is removed, e.g., using a wet etch process or a dry etch process, thereby forming a trench 970. Then, the bottom of the trench 970, which is formed by a portion of the tunnel dielectric layer 954 and the nitride layer 956 is removed by means of a spacer etching, thereby exposing an interconnect region 972 of the carrier 760 between the second source/drain region 950 of the select gate 132a and the first source/drain region 950 of the select gate 138a. Additionally, arsenic or another similar is implanted into the bottom of the interconnect region 972 to form a conductive junction coupled to the source/drain junctions of the adjacent select gates (e.g., 132a and 138a). The implantation of the doping atoms such as arsenic is carried out with a doping concentration in the range of 1019 cm-3 to 1020 cm-3. The resulting structure 974 is illustrated in FIG. 9R.

Next, poly-silicon 976 is deposited within the trench 970, e.g., through a doped in situ chemical-vapor deposition (CVD) process, the poly-silicon layer 976 subsequently planarized level with the nitride layer 956 of the stack structures through CMP. The resulting structure 978 is illustrated in FIG. 9S.

FIGS. 9T-9V illustrate cross-sectional view BB (as indicated in FIG. 9A) of the common source/drain memory array portion in various states of manufacture in accordance with the present invention. As shown in FIG. 9A, the view is taken across the bit line contact 120a, which is formed between (and possibly vertically offset from) adjacent control lines 710. FIGS. 9T-9V depict cross-sectional views of four select gates, 132a, 134a, 136a, and 138a to more clearly illustrate the invention, although the cross-sectional views of only two select gates would be shown in view BB indicated in FIG. 9A. The cell structure illustrated is a Flash floating gate architecture, but as noted above, select gates of different technologies and/or architectures may be used instead.

The process begins at the point in construction shown in FIG. 9S, and continues with the deposition of the oxide layer 980, e.g., silicon oxide layer, the oxide layer 980 then being planarized through a CMP process. FIG. 9T illustrates the resulting structure 982.

Subsequently, the oxide layer 980 is etched to form a trench within which the bit line interconnect 120a is formed in contact with the interconnection post 976. In a particular embodiment, tungsten is used as the material to form the bit line contact 120a, although other materials may be used in alternative embodiments. The resulting structure 984 is shown in FIG. 9U.

Next, a bit line (e.g., 120) is formed in contact with the bit line contact 120a, the bit line metal patterned and etched to its final shape. In a particular embodiment, the bit line 120 is formed from aluminum, although other metals may be used in other embodiments. The resulting structure 986 is shown in FIG. 9V.

The present invention provides a bit line interconnect structure operable to supply bit line voltages to any one of multiple memory cell strings. Further, the footprint of the bit line interconnect is uniquely small, and its implementation over a smaller area of the memory area permits increased storage density of the memory device.

In the embodiments of the invention, the hardmask layer(s) may be made of silicon oxide, silicon nitride or carbon. Any other suitable material may be used in alternative embodiments of the invention. Furthermore, in a further alternative embodiment of the invention, another mask layer, e.g., made of photoresist material may be used instead of the hardmask layer(s), where appropriate.

As readily appreciated by those skilled in the art, the described processes may be implemented in hardware, software, firmware or a combination of these implementations as appropriate. In addition, some or all of the described processes may be implemented as computer readable instruction code resident on a computer readable medium (removable disk, volatile or non-volatile memory, embedded processors, etc.), the instruction code operable to program a computer of other such programmable device to carry out the intended functions.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A memory array, comprising:
a plurality of memory cell strings comprising first, second, third and forth memory cell strings, each of the first, second, third, and fourth memory cell strings comprising a plurality of serially-coupled memory cells, including a first memory cell and a last memory cell;
a first bit line; and
a first interconnect, coupled to the first bit line and to each of the first, second, third and fourth memory cell strings, the first interconnect comprising first, second, third and fourth string input select gates, each input select gate having a first terminal coupled to the first bit line, and a second terminal coupled to a respective one of the first, second, third or fourth memory cell strings.

2. The memory array of claim 1, wherein two of the first, second, third, or forth string input select gates comprise a through connection and the remaining two of the first, second, third, or fourth string input select gates comprise a switch.

3. The memory array of claim 1, wherein the first string input select gate is coupled between the first bit line and the first memory cell in the first string;
the second string input select gate is coupled between the first bit line and the first memory cell in the second string;
the third string input select gate is coupled between the first bit line and the first memory cell in the third string; and
the fourth string input select gate is coupled between the first bit line and the first memory cell in the fourth string.

4. The memory array of claim 3, wherein either:
(i) the second and third string input select gates comprise a through connection, and the first and fourth string input select gates comprise switches, or
(ii) the second and third string input select gates comprise switches, and the first and fourth string input select gates comprise through connections.

5. The memory array of claim 1, wherein the first and third strings of serially-coupled memory cells are substantially aligned along a first longitudinal axis, the second and fourth strings are substantially aligned along a second longitudinal axis, and the first bit line is disposed between the first and second longitudinal axes.

6. The memory array of claim 1, wherein memory cells included within the first, second, third and fourth strings of serially-coupled memory cells comprise non-volatile memory cells.

7. The memory array of claim 1, wherein the last memory cell in each of the first and second memory cell strings is coupled to a first common source/drain line, and the last memory cell in each of the third and fourth memory cell strings is coupled to a second common source/drain line.

8. The memory array of claim 7, further comprising:
a first string output select gate coupled between the last memory cell in the first memory cell string and the first common source/drain line;
a second string output select gate coupled between the last memory cell in the second memory cell string and the first common source/drain line;
a third string output select gate coupled between the last memory cell in the third memory cell string and the second common source/drain line;
a fourth string output select gate coupled between the last memory cell in the fourth memory cell string and the second common source/drain line.

9. The memory array of claim 8, further comprising:
a fifth memory cell string comprising a string of serially-coupled memory cells, including a first memory cell and a last memory cell;
a sixth memory cell string comprising a string of serially-coupled memory cells, including a first memory cell and a last memory cell;
a second bit line; and
a second interconnect coupled to the second bit line and to each of the fifth and sixth memory cell strings, the second interconnect comprising a fifth string input select gate coupled between the second bit line and the fifth memory cell string, and a sixth string input select gate coupled between the second bit line and the sixth memory cell string.

10. The memory array of claim 9, wherein one of the fifth string input select gate or the sixth string input select gate comprises a through connection, and the other one of the fifth string input select gate or sixth string output select gate comprises a switch.

11. The memory array of claim 9, wherein the memory cells included within the first, second, third, fourth, fifth and sixth strings comprise non-volatile memory cells.

12. The memory array of claim 9, wherein the last memory cell in the fifth string is coupled to the first common source/drain line, and the last memory cell in the sixth string is coupled to a second common source/drain line.

13. The memory array of claim 12, further comprising:
a fifth string output select gate coupled between the last memory cell in the fifth string and the first common source/drain line; and
a sixth string output select gate coupled between the last memory cell in the sixth string and the second common source/drain line.

14. The memory array of claim 1, further comprising:
a fifth memory cell string comprising a plurality of serially-coupled memory cells, including a first memory cell and a last memory cell;
a second bit line; and
a second interconnect coupled to the second bit line and to the each of the second and fifth memory cell strings, the second interconnect comprising a second string output select gate coupled between the second memory cell string and the second bit line, and a fifth string output select gate coupled between the fifth memory cell string and the second bit line.

15. The memory array of claim 14, further comprising:
a sixth memory cell string comprising a plurality of serially-coupled memory cells, including a first memory cell and a last memory cell; and
a third interconnect coupled to the second bit line and to the each of the fourth and sixth memory cell strings, the third interconnect comprising a fourth string output select gate coupled between the fourth memory cell string and the second bit line, and a sixth string output select gate coupled between the sixth memory cell string and the second bit line.

16. The memory array of claim 15, wherein one of the fourth or sixth string output select gates comprises a through connection, and the other one of the fourth or sixth string output select gates comprises a switch.

17. The memory array of claim 15, wherein the memory cells included within the first, second, third, fourth, fifth and sixth memory cell strings comprise non-volatile memory cells.

18. The memory array of claim 15, further comprising:
a third bit line; and
a fourth interconnect coupled to the third bit line and to each of the fifth and sixth memory cell strings, the fourth interconnect comprising a fifth string input select gate coupled between the fifth memory cell string and the third bit line, and a sixth string input select gate coupled between the sixth memory cell string and the third bit line.

19. The memory array of claim 18, wherein one of the fifth or sixth string input select gates comprises a through connection, and the other one of the fifth or sixth string input select gates comprises a switch.

20. The memory array of claim 19, wherein the memory cells included within the first, second, third, fourth, fifth and sixth memory cell strings comprise non-volatile memory cells.

21. A method of manufacturing a memory array, the method comprising:
forming first, second, third, and fourth memory cell strings, each of the memory cell strings comprising a plurality of serially-coupled memory cells, including a first memory cell and a last memory cell;
forming a first bit line operable to provide a voltage to the memory cells in each of the first, second, third, and fourth memory cell strings; and
forming a first interconnect operable to provide an electrical interconnection between the first bit line and each of the first, second, third and fourth strings, the first interconnect comprising first, second, third and fourth string input select gates, each of the respective input select gates coupled between the first bit line and a respective one of the first, second, third or fourth memory cell strings.

22. The method of claim 21, wherein forming a first interconnect further comprises configuring two of the first, second, third, and fourth string input select gates to operate as switches, and configuring the remaining two of the first, second, third and fourth string input select gates to operate as through connections.

23. The method of claim 21, wherein the first and third memory cell strings are formed to substantially align along a first longitudinal axis, the second and fourth memory cell strings are formed to substantially align along a second longitudinal axis, and the first bit line is formed between the first and second longitudinal axes.

24. The method of claim 21, wherein the first, second, third and fourth input select gates comprise field effect transistors, each having a first terminal coupled to the first bit line, a second terminal coupled to one of the respective first, second, third or fourth strings, and a gate terminal operable to control conduction between the first terminal and second terminal; and
wherein configuring two of the first, second, third and fourth input select gates comprises implanting an active region between the first terminal and the second terminal of two of the field effect transistors to render said active region conductive.

25. The method of claim 21, wherein the memory cells within each of the first, second, third, fourth memory cell strings comprise non-volatile memory cells.

26. The method of claim 21, further comprising:
forming a first common source/drain line coupled to each of the last memory cells in the first and second memory cell strings, and
forming a second common source/drain line coupled to each of the last memory cells in the third and fourth memory cell strings.

27. The method of claim 26, further comprising:
forming a first string output select gate coupled between the last memory cell in the first memory cell string and the first common source/drain line;
forming a second string output select gate coupled between the last memory cell in the second memory cell string and the first common source/drain line;
forming a third string output select gate coupled between the last memory cell in the third memory cell string and the second common source/drain line; and
forming a fourth string output select gate coupled between the last memory cell in the fourth memory cell string and the second common source/drain line.

28. The method of claim 21, further comprising:
forming a fifth memory cell string, comprising a plurality of serially-coupled memory cells including a first memory cell and a last memory cell;
forming a second bit line operable to provide a voltage to the memory cells in each of the second and fifth memory cell strings; and
forming a second interconnect operable to provide an electrical interconnection between the second bit line;
wherein forming the first, second, third and fourth memory cell strings, comprises:
constructing a second string output select gate coupled between the second bit line and the last memory cell in the second memory cell string;
constructing a fifth string output select gate coupled between the second bit line and the last memory cell in the fifth memory cell string; and
configuring one of the second and fifth string output select gates to operate as a switch, and configuring the remaining one of the second and fifth string output select gates to operate as a through connection.

29. The method of claim 28, wherein the first and third strings are formed to substantially align along a first longitudinal axis, the second and fourth strings are formed to substantially align along a second longitudinal axis, and the fifth string is formed along a third longitudinal axis; and
wherein the first bit line is formed between the first and second longitudinal axes, and the second bit line is formed between the second and third longitudinal axis.

30. The method of claim 28, wherein constructing the second and fifth string output select gates comprises constructing field effect transistors, each having a first terminal coupled to the first bit line, a second terminal coupled to one of the respective second or fifth strings, and a gate terminal operable to control conduction between the first terminal and second terminal.

31. The method of claim 21, wherein the memory cells within each of the first, second, third, fourth, and fifth strings comprise non-volatile memory cells.
